(19) United States
(12) Patent Application Publication
(10) Pub. No.: US 2010/0003599 A1
(43) Pub. Date: Jan. 7, 2010

(54) METHOD FOR PRODUCING CURRENT COLLECTOR FOR NON-AQUEOUS ELECTROLYTE SECONDARY BATTERY, METHOD FOR PRODUCING ELECTRODE FOR NON-AQUEOUS ELECTROLYTE SECONDARY BATTERY, AND NON-AQUEOUS ELECTROLYTE SECONDARY BATTERY

(76) Inventors: Takashi Nonoshita, Osaka (JP); Takuhiro Nishimura, Osaka (JP); Hitoshi Katayama, Osaka (JP); Masanori Sumihara, Osaka (JP); Seiichi Kato, Osaka (JP)

Correspondence Address: MCDERMOTT WILL & EMERY LLP, 600 13TH STREET, NW, WASHINGTON, DC, 20005-3096, US

(21) Appl. No.: 12/447,230

(22) PCT Filed: Nov. 15, 2007
(86) PCT No.: PCT/JP2007/072221

§ 371 Date: Apr. 24, 2009

(30) Foreign Application Priority Data
Nov. 15, 2006 (JP) 2006-308774
Nov. 29, 2006 (JP) 2006-321495
Nov. 29, 2006 (JP) 2006-321496
Mar. 9, 2007 (JP) 2007-059443
Mar. 28, 2007 (JP) 2007-083733
Nov. 15, 2007 (JP) 2007-296872

(51) Int. Cl. H01M 4/02; B23K 26/38; B05D 5/12; C23C 14/34; H05H 1/24

(52) U.S. Cl. 429/209; 29/623.1; 219/68; 427/58; 204/192.15; 427/569

(57) ABSTRACT

An objective is to improve the mechanical strength and the durability of a current collector for a non-aqueous electrolyte secondary battery and to allow an active material layer to be efficiently carried on the surface of the current collector with high adhesion. This objective is achieved with the use of a pair of processing means being disposed such that the surfaces thereof are in press contact with each other to form a press nip for passing a sheet material therethrough and having a plurality of recesses formed on the surface of at least one of the processing means, by passing a metallic foil for current collector through the press nip between the processing means to perform compression, thereby to form a plurality of projections on at least one surface of the metallic foil for current collector by partial plastic deformation associated with the compression.

### TECHNICAL FIELD

The present invention relates to a method for producing a current collector for a non-aqueous electrolyte secondary battery, a method for producing an electrode for a non-aqueous electrolyte secondary battery, and a non-aqueous electrolyte secondary battery. More specifically, the present invention mainly relates to improvements of a current collector for a non-aqueous electrolyte secondary battery.

### BACKGROUND ART

Lithium secondary batteries have high electric potential and high capacity and can be comparatively easily made smaller in size and lighter in weight. In view of these features, the use of such lithium secondary batteries has been significantly increased in recent years mainly as power sources for portable electronic equipment. With respect to typical lithium secondary batteries, improvements in the electric potential and the capacity have been achieved by using a carbonaceous material capable of absorbing and desorbing lithium, and the like as a negative electrode active material and using a composite oxide containing a transition metal and lithium, such as LiCoO₂, as a positive electrode active material. However, as portable electronic equipment becomes more multi-functional and thus power-consuming, with respect to lithium secondary batteries which are used as the power sources thereof, it is expected to ameliorate the deterioration in characteristics due to repeated charge/discharge cycles.

Electrodes serving as power generation elements of lithium secondary batteries each include a current collector and an active material layer. The active material layer is generally formed by applying a material mixture slurry onto one surface or both surfaces of the current collector, drying the slurry, and then performing press molding. The material mixture slurry is prepared by mixing a positive or negative electrode active material, a binder, and, as needed, a conductive agent, and dispersing the resultant mixture into a dispersing medium.

Here, one of the causes of the deterioration in characteristics due to repeated charge/discharge cycles is in the reduction in bonding strength between the active material layer formed on the surface of the current collector and the current collector. In lithium secondary batteries, the electrodes expand and contract as charge/discharge cycles are repeated, causing the bonding strength between the current collector and the active material layer to be decreased at the interface between the two and thus causing the active material layer to be separated from the current collector. As a result, the characteristics will deteriorate.

In order to enhance the bonding strength between the current collector and the active material layer, it is effective to increase the contact area between the active material layer and the current collector at the interface between the two. In view of this, a method of roughening the surface of a current collector, a method of forming projections and depressions on the surface of a current collector, and other methods have been proposed.

Examples of the method of roughening the surface of a current collector include a method of etching the surface of a current collector by electrolysis, a method of allowing the same metal contained in a current collector to be precipitated on the surface of the current collector by electrolysis, and other methods.

As the method of forming projections and depressions on the surface of a current collector, for example, a method of forming minor projections and depressions on the surface by allowing fine particles to collide with the surface of a rolled copper foil serving as the current collector at high speeds has been proposed (see, for example, Patent Document 1). According to Patent Document 1, a current collector locally having random projections and depressions can be formed, whereas it is difficult to form a current collector having uniform projections and depressions in its length and width directions since there is a variation in the velocity of the fine particles ejected from the nozzle.

Further, a method of forming projections and depressions by irradiating a metallic foil with laser beams so that the metallic foil has a surface roughness of 0.5 to 10 μm as a 10-point average roughness has been proposed (see, for example, Patent Document 2). According to Patent Document 2, depressions are formed by irradiating a metallic foil with laser beams to locally heat the metallic foil and vaporize metal. The continuous irradiation of laser beams makes it possible to form projections and depressions all over the surface of the metallic foil. However, since the laser beams are linearly applied, the metallic foil is locally heated to a high temperature equal to or higher than the melting point of the metallic foil. Because of this, it is difficult to prevent the occurrence of crinkling, wrinkling, and warping on the metallic foil. In addition, in the case where a metallic foil having a thickness of 20 μm or less, such as a current collector for a lithium secondary battery, is subjected to laser machining, disadvantageously, the metallic foil may be perforated because of the variation in the output power of the laser.

Furthermore, a method of forming projections and depressions on a current collector by bringing a roller whose surface is provided with protrusions and recesses in contact with another roller whose surface is provided with a hard rubber layer in such a manner that the axes of the rollers are arranged in parallel to each other, and passing a current collector through the contact portion between the two rollers has been proposed (see, for example, Patent Document 3). According to Patent Document 3, projections and depressions are formed on the current collector for the purpose of improving the output power density of a lithium secondary battery without reducing the thickness of the active material layer. According to Patent Document 3, the current collector, although passed through the contact portion between the rollers, is unlikely to undergo plastic deformation since the roller with a hard rubber layer provided on its surface is used.

Yet further, in order to improve the bonding strength and the electron conductivity between the current collector and the active material layer, a current collector having specific projections and depressions has been proposed (see, for example, Patent Document 4). FIGS. 20(a) to (e) are perspective views schematically showing a configuration of the current collector of Patent Document 4. On the current collector of Patent Document 4, projections and depressions are regularly formed in such a manner that when a local portion on one surface of the metallic foil is depressed, a portion corresponding to the local portion on the other surface of the metallic foil is projected outwardly from the other surface. Such a current collector fails to have a sufficient mechanical strength. In addition, if an active material layer is formed on such a current collector, the active material layer tends to have a non-uniform thickness, which will adversely affect the battery performance.

According to Patent Documents 1 to 4, when depressions are formed on one surface of the metallic foil, portions corresponding to the depressions on the other surface are unavoidably formed into projections. It is difficult, therefore, to prevent the occurrence of crinkling, wrinkling, and warping on the metallic foil in forming projections and depressions.

Still further, an electrode including: a current collector made of a punching metal having a porosity of 20% or less and having projections and depressions formed by embossing; and a layer made of an active material filling the depressions of the current collector, in which the projections of the current collector are exposed or the active material adheres to the projections, has been proposed (see, for example, Patent Document 5). FIG. 21 is a longitudinal cross-sectional view schematically showing a configuration of electrodes 101 to 103 of Patent Document 5. The electrode 101 shown in FIG. 21(a) includes a current collector 110 with projections and depressions formed thereon and a layer 111 of active material filling depressions 110b of the current collector 110. The active material layer 111 adheres to the surfaces of projections 130a of the current collector 110. In the electrodes 102 and 103 shown in FIGS. 21(b) and (c), projections 120a and 130a of current collectors 120 and 130 are both exposed. According to Patent Document 5, the projections and depressions are formed by embossing the punching metal having a porosity of 20% or less, the resultant current collector fails to have a sufficient mechanical strength. This may disadvantageously result in tearing of the electrode.

Moreover, an electrode including a current collector and an active material layer, in which the value of (Surface roughness Ra of active material layer)−(Surface roughness Ra of current collector) is 0.1 μm or more has been proposed (see, for example, Patent Document 6). Normally, when a thin film of active material is formed on a surface of the current collector by vacuum vapor deposition and the like, the thin film will have a surface roughness approximately equal to that of the current collector. On the other hand, in Patent Document 6, the thin film formed by the normal method is subjected to a treatment, such as sand-blasting and surface-grinding, so that the surface roughness of the thin film is adjusted to the foregoing specific value. By doing this, it is intended to relieve the stress due to expansion of the active material. The technique disclosed in Patent Document 6 is effective to some extent in that cracks on the active material can be prevented, but disadvantageous in that the exfoliation of the thin film from the current collector, the deformation of the electrode, and the like will easily occur since the thin film of active material is formed all over the surface of the current collector. As a result, the charge/discharge cycle characteristics will deteriorate.

Patent Document 1: Japanese Laid-Open Patent Publication No. 2002-79466

Patent Document 2: Japanese Laid-Open Patent Publication No. 2003-258182

Patent Document 3: Japanese Laid-Open Patent Publication No. Hei 8-195202

Patent Document 4: Japanese Laid-Open Patent Publication No. 2002-270186

Patent Document 5: Japanese Laid-Open Patent Publication No. 2005-32642

Patent Document 6: Japanese Laid-Open Patent Publication No. 2002-279972

### DISCLOSURE OF THE INVENTION

### Problem to be Solved by the Invention

An object of the present invention is to provide a method for producing a current collector for a non-aqueous electrolyte secondary battery, the current collector having a plurality of projections that are formed on at least one surface thereof without undergoing compression and being capable of efficiently carrying an active material layer, as well as having a high mechanical strength.

Another object of the present invention is to provide a method for producing an electrode for a non-aqueous electrolyte secondary battery, the electrode including: the current collector obtained by the present method for producing a current collector for a non-aqueous electrolyte secondary battery; and an active material layer.

A further object of the present invention is to provide a non-aqueous electrolyte secondary battery including the electrode obtained by the present method for producing an electrode for a non-aqueous electrolyte secondary battery.

### Means for Solving the Problem

The present invention relates to a method for producing a current collector for a non-aqueous electrolyte secondary battery using a pair of processing means being disposed such that the surfaces thereof are in press contact with each other to form a press nip for passing a sheet material therethrough and having a plurality of recesses formed on the surface of at least one of the pair of processing means, the method comprising the step of passing a metallic foil for current collector through the press nip between the pair of processing means to perform compression, thereby to form a plurality of projections on at least one surface of the metallic foil for current collector.

Preferably, the end surfaces of the projections have a surface roughness approximately equal to a surface roughness of the metallic foil for current collector before undergoing the compression.

Preferably, the cross section of each of the recesses in a direction perpendicular to the surface of the processing means has a tapered shape in which the width of the cross section in a direction parallel to the surface of the processing means gradually narrows from the surface of the processing means toward the bottom of the recess.

Preferably, the compression is performed such that a volume of the projections is equal to or less than a volume of an internal space of the recesses.

Preferably, the compression is performed such that the volume of the projections is equal to or less than 85% of the volume of the internal space of the recesses.

Preferably, in the processing means having the plurality of recesses formed on its surface, each boundary between the recesses and the surface of the processing means is formed of a curved surface.

Preferably, the curved surface of the boundary between the recesses and the surface of the processing means is formed by forming the recesses by laser machining and removing a bulge produced in the laser machining on the boundary between the recesses and the surface of the processing means.

Preferably, the bulge is removed by grinding with diamond particles having an average particle size of 30 μm or more and less than 53 μm.

Preferably, a plurality of grooves each having a width of 1 μm or less and a depth of 1 μm or less are formed on the boundary between the recesses and the surface of the processing means.

Preferably, the grooves are formed by grinding with diamond particles having an average particle size of 5 μm or less.

Preferably, the pair of processing means is a pair of rollers having a plurality of recesses formed on a surface of at least one of the pair of rollers.

Preferably, a surface coating layer containing a cemented carbide or an alloy tool steel or chromium oxide is formed on the surface of the roller having the plurality recesses formed thereon and on the surfaces of the recesses facing the internal space thereof.

Preferably, a protection layer containing an amorphous carbon material is formed on the surface of the surface coating layer.

Preferably, the surface coating layer and the protection layer are formed by at least one vapor phase growth method selected from the group consisting of a physical vapor deposition utilizing sputtering, a physical vapor deposition utilizing ion injection, a chemical vapor deposition utilizing heat vapor deposition, and a chemical vapor deposition utilizing plasma vapor deposition.

Preferably, at least one of the pair of rollers is a roller having a ceramic layer provided on its surface, and the plurality of recesses are formed on the surface of the ceramic layer.

Preferably, a lubricant is applied and dried on the surface of the roller or on the surface of the metallic foil for current collector.

Preferably, the lubricant contains a fatty acid.

The present invention further relates to a current collector for a non-aqueous electrolyte secondary battery comprising a base made of a metallic foil for current collector, and a plurality of projections formed so as to extend outwardly from at least one surface of the base, wherein each boundary between the surface of the base and the projections is formed of a curved surface.

The present invention furthermore relates to a method for producing an electrode for a non-aqueous electrolyte secondary battery, the method comprising the step of allowing a positive electrode active material or a negative electrode active material to be carried on the surface of a current collector for a non-aqueous electrolyte secondary produced by any one of the above-described methods for producing a current collector for a non-aqueous electrolyte secondary battery or on the surface of the above-described current collector for a non-aqueous electrolyte secondary.

Preferably, the positive electrode active material or the negative electrode active material is carried on the surfaces of the projections on the current collector for a non-aqueous electrolyte secondary battery.

The present invention further relates to a non-aqueous electrolyte secondary battery comprising a positive electrode, a negative electrode, a separator, and a non-aqueous electrolyte, wherein at least one of the positive electrode and the negative electrode is an electrode produced by the above-described method for producing an electrode for a non-aqueous electrolyte secondary battery.

### EFFECTS OF THE INVENTION

According to the method for producing a current collector for a non-aqueous secondary battery of the present invention, since the projections are formed without undergoing compression, it is possible to provide a current collector having an improved mechanical strength and an excellent durability.

Further, the projections are formed by plastic deformation without undergoing compression. The end surfaces of the projections are formed without undergoing compression and little influenced by plastic deformation associated with compression, and therefore has a surface roughness approximately equal to a surface roughness of the metallic foil for current collector before undergoing compression. A current collector having such projections has further improved mechanical strength and thus has a further improved durability. In addition, such a current collector exhibits strong adhesion with an active material layer to be carried thereon.

Furthermore, in a current collector including a base and a plurality of projections formed so as to extend outwardly from at least one surface of the base, by forming the boundary between the surface of the base and each of the projections into a curved surface, it is possible to further improve the mechanical strength and the durability of the current collector. It is further possible to form the projections at lower pressure in the process of compression and to improve the releasability from the processing means of the current collector after the process of compression.

### BRIEF DESCRIPTION OF THE DRAWINGS

FIG. 1 is a series of longitudinal cross-sectional views schematically showing a production method of a current collector as one embodiment of the present invention.

FIG. 2 is a series of longitudinal cross-sectional views schematically explaining plastic deformation that occurs in association with compression of a metallic foil for current collector.

FIG. 3 is a side view schematically showing a configuration of a current collector production apparatus.

FIG. 4 is an enlarged perspective view showing a configuration of a main part of the current collector production apparatus shown in FIG. 3.

FIG. 5 is a set of drawings showing a configuration of a roller used for compression. FIG. 5(a) is a perspective view showing an appearance of the roller. FIG. 5(b) is an enlarged perspective view showing a surface region of the roller shown in FIG. 5(a).

FIG. 6 is a series of longitudinal cross-sectional views schematically showing another production method of a current collector as one embodiment of the present invention.

FIG. 7 is a longitudinal cross-sectional view schematically showing a configuration of a current collector obtained by the production method of a current collector for a non-aqueous electrolyte secondary battery of the present invention.

FIG. 8 is a series of longitudinal cross-sectional views schematically showing the production method of a current collector shown in FIG. 7.

FIG. 9 is a set of drawings showing a configuration of another roller used for compression. FIG. 9(a) is a perspective view showing an appearance of the roller. FIG. 9(b) is an enlarged perspective view showing a surface region of the roller shown in FIG. 9(a). FIG. 9(c) is an enlarged perspective view showing a recess formed on the peripheral surface of the roller shown in FIG. 9(b).

FIG. 10 is a longitudinal cross-sectional view schematically showing a configuration of another current collector obtained by the production method of a current collector for a non-aqueous electrolyte secondary battery of the present invention.

FIG. 11 is a series of longitudinal cross-sectional views schematically showing the production method of a current collector shown in FIG. 10.

FIG. 12 is a partially exploded perspective view schematically showing a configuration of a wound non-aqueous electrolyte secondary battery as one embodiment of the present invention.

FIG. 13 is a longitudinal cross-sectional view schematically showing a configuration of a laminated non-aqueous electrolyte secondary battery as one embodiment of the present invention.

FIG. 14 is a set of drawings schematically showing a configuration of a current collector obtained in Example 5. FIG. 14(a) is a perspective view. FIG. 14(b) is a longitudinal cross-sectional view.

FIG. 15 is a set of drawings schematically showing a configuration of a current collector obtained in Example 6. FIG. 15(a) is a perspective view. FIG. 15(b) is a longitudinal cross-sectional view.

FIG. 16 is a set of a set of drawings schematically showing a configuration of a current collector obtained in Example 24. FIG. 16(a) is a perspective view. FIG. 16(b) is a longitudinal cross-sectional view.

FIG. 17 is a set of drawings schematically showing a configuration of a current collector obtained in Example 25. FIG. 17(a) is a perspective view. FIG. 17(b) is a longitudinal cross-sectional view.

FIG. 18 is an electron micrograph of the cross section of a current collector obtained in Example 1.

FIG. 19 is an electron micrograph of the cross section of a current collector obtained in Comparative Example 1.

FIG. 20 is a set of perspective views schematically showing the configuration of a conventional current collector.

FIG. 21 is a set of longitudinal cross-sectional views schematically showing the configuration of a conventional electrode.

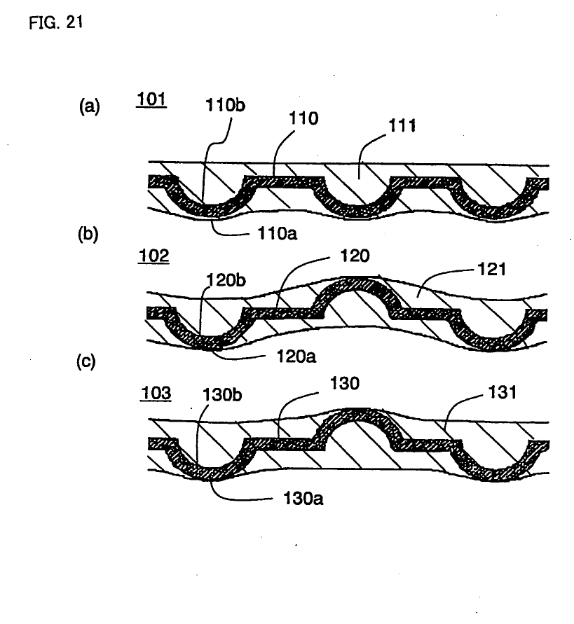

According to the production method of a current collector for a non-aqueous secondary battery of the present invention, in the steps of forming projections on the surface of a metallic foil for current collector, allowing an electrode active material to be carried on the projections of a current collector, and other steps, the occurrence of local deformation, deflection, warping, tearing, and the like on the metallic foil for current collector and the current collector can be prevented. In addition, also in the steps of forming an electrode by allowing an electrode active material on the projections of the current collector, slitting the electrode into a predetermined width, and other steps, the separation of the electrode active material from the current collector can be suppressed. Thus, finally, it is possible to obtain a highly reliable non-aqueous electrolyte secondary battery.

### BEST MODE FOR CARRYING OUT THE INVENTION

### Method for Producing Current Collector for Non-Aqueous Electrolyte Secondary Battery

The method for producing a current collector for a non-aqueous electrolyte secondary battery of the present invention (herein after simply referred to as the “production method of a current collector”) is characterized in that a metallic foil for current collector is passed through a press nip between a pair of processing means to perform compression. More specifically, the method is characterized by employing the foregoing configuration and allowing partial plastic deformation to occur on a surface of the metallic foil for current collector, thereby to form projections whose end surfaces are little influenced by compression and plastic deformation.

The pair of processing means as herein referred to is a pair of processing means disposed such that the surfaces thereof are in press contact with each other to form a press nip for passing a sheet material therethrough, and having a plurality of recesses formed on the surface of at least one of the processing means. A preferred pair of processing means is a pair of rollers. In the pair of rollers, a plurality of recesses are formed on the surface of at least one of the rollers. The compression of the present invention is performed by, for example, passing a metallic foil for current collector through the press nip between the pair of rollers to mechanically press the metallic foil for current collector and allow the metallic foil for current collector to undergo partial plastic deformation. When the current collector having projections on its surface is formed by compression using a pair of rollers, the separation of the projections from the current collector can be prevented almost without fail. Moreover, the current collector having projections on its surface can be produced with low costs and high productivity.

According to the production method of a current collector of the present invention, a current collector for a non-aqueous electrolyte secondary battery (hereinafter simply referred to as a “current collector”) in which a plurality of projections are formed on one surface in the thickness direction thereof can be provided.

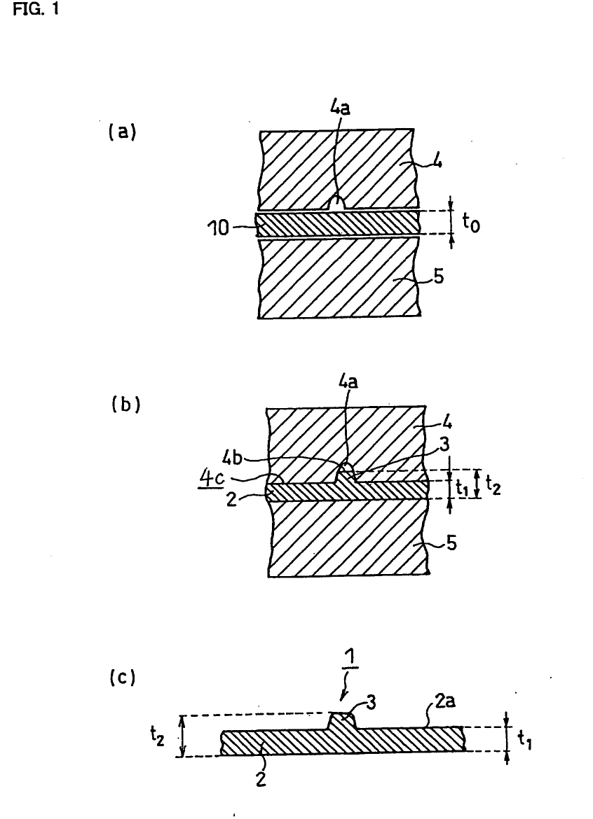

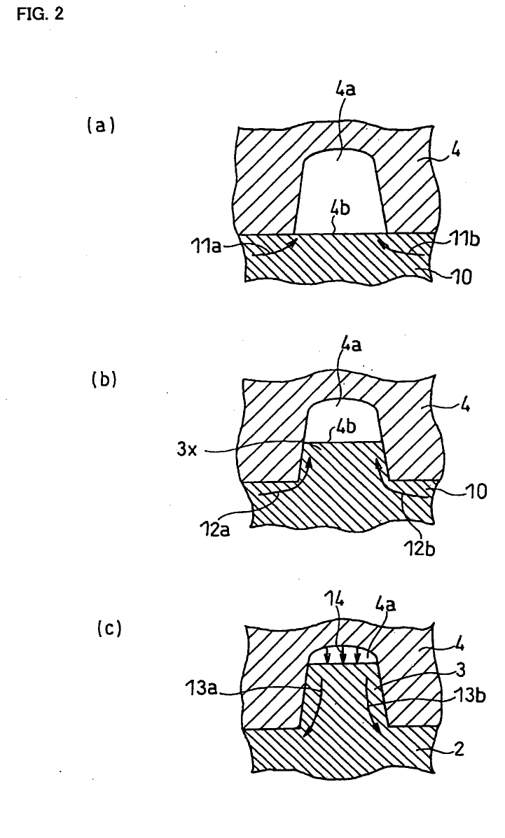

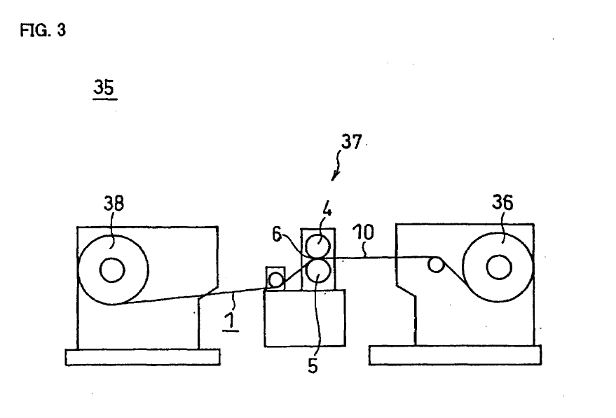

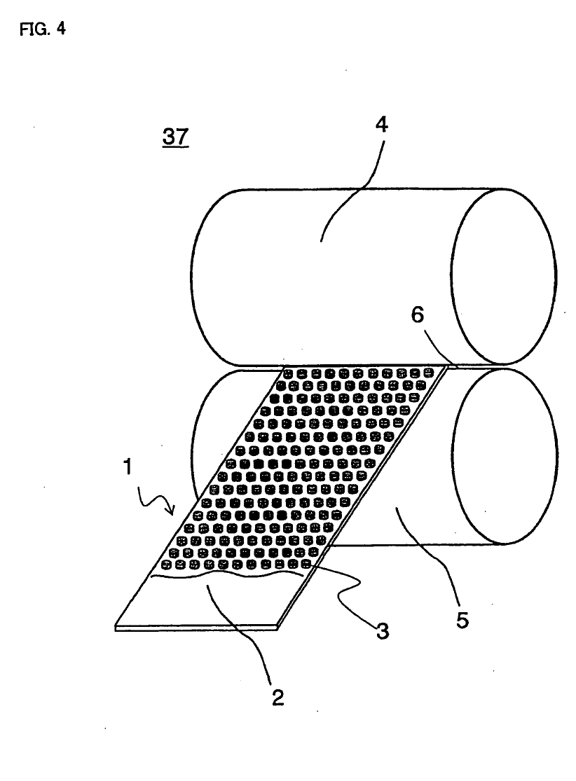

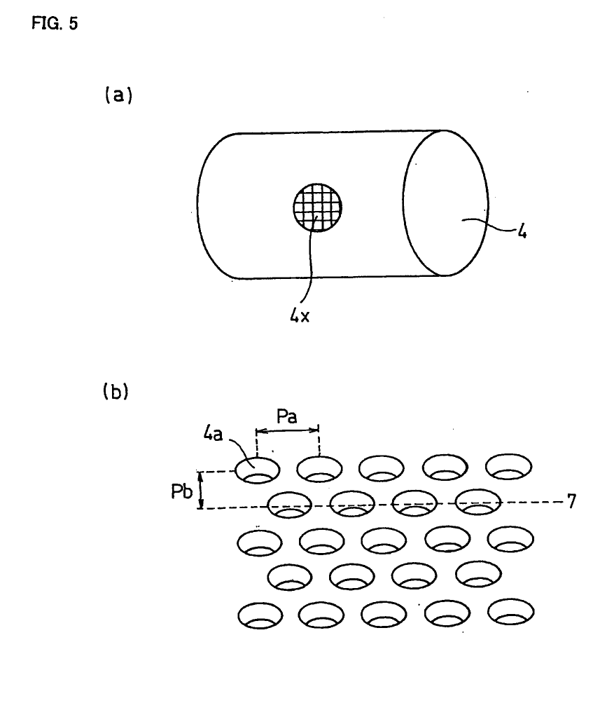

FIG. 1 is a series of longitudinal cross-sectional views schematically showing the process of compression of a metallic foil 10 for current collector as one embodiment of the present invention. FIG. 2 is a series of longitudinal cross-sectional views schematically explaining plastic deformation due to the compression of the metallic foil 10 for current collector. FIG. 3 is a side view schematically showing a configuration of a current collector production apparatus 35. FIG. 4 is an enlarged perspective view showing a configuration of a main part (a processing means 37) of the current collector production apparatus 35 shown in FIG. 3. FIG. 5 is a set of drawings showing a configuration of a roller 4 used for compression. FIG. 5(a) is a perspective view showing an appearance of the roller 4. FIG. 5(b) is an enlarged perspective view showing a surface region 4x of the roller 4 shown in FIG. 5(a).

The production method of a current collector of the present invention is carried out, for example, by using the current collector production apparatus 35 shown in FIG. 3. The current collector production apparatus 35 includes a metallic foil feeding means 36, the processing means 37, and a current collector winding-up means 38.

The metallic foil feeding means 36 is specifically a metallic foil feeding roller. The metallic foil feeding roller is axially supported by a supporting means (not shown) in such a manner that the roller is rotatable around the axis. On the peripheral surface of the metallic foil feeding roller, the metallic foil 10 for current collector is wound. This metallic foil 10 for current collector is fed to a press nip 6 in the processing means 37.

The metallic foil 10 for current collector is a metallic foil made of a metallic material that does not electrochemically react with lithium. In the case of forming a current collector 1 for negative electrode from the metallic foil 10 for current collector, it is possible to use a metallic foil made of copper, nickel, iron, an alloy containing at least one of these, and the like as the metallic foil 10 for current collector. Among these, a metallic foil made of copper or a copper alloy is preferred. Examples of the copper alloy include a precipitation hardening alloy, such as a zinc-containing copper, a tin-containing copper, a silver-containing copper, a zirconium-containing copper, chromium copper, tellurium copper, titanium copper, beryllium copper, iron-containing copper, phosphorus-containing copper, and aluminum copper; a composite alloy of two or more of these alloys; and the like. Examples of the metallic foils of copper and a copper alloy include an electrolytic copper foil, an electrolytic copper alloy foil, a rolled copper foil, a copper alloy foil, and a rolled copper alloy foil; a foil obtained by roughening the surface of the above-listed foils; and the like. The thickness of the metallic foil for negative electrode is not particularly limited, but preferably about 5 to 100 μm.

In the case of forming the current collector 1 for positive electrode from the metallic foil 10 for current collector, it is possible to use a metallic foil made of aluminum, an aluminum alloy, stainless steel, titanium, and the like as the metallic foil 10 for current collector. The thickness of the metallic foil for positive electrode is not particularly limited, but preferably about 5 to 100 μm. A metallic foil obtained by roughening the surface of the above-listed foils may be used.

The processing means 37 includes the roller 4 and a roller 5 as shown in FIG. 3 and FIG. 4. The rollers 4 and 5 are in press contact with each other such that the axes thereof are in parallel with each other, to form the press nip 6. The press nip 6 allows the passage of a sheet material such as the metallic foil 10 for current collector. The rollers 4 and 5 are each axially supported by a supporting means (not shown) in such a manner that each roller is rotationally drivable around its axis by a driving means (not shown). The rollers 4 and 5 may be both used as a driving roller. Alternatively, one of the rollers 4 and 5 may be used as a driving roller and the other may be used as a follower roller that rotates in association with the rotation of the driving roller. The metallic foil 10 for current collector is guided from the entrance to the exit of the press nip 6 by the rotational driving of the rollers 4 and 5 and is compressed while passing through the press nip 6, to be formed into the current collector 1 as shown in FIG. 1(c).

The current collector 1 includes a base 2 and a plurality of projections 3. The base 2 is a plate-like portion of the metallic foil 10 for current collector compressed in its thickness direction. The projections 3 are protruding portions formed so as to extend outwardly from one surface 2a of the base 2. The projections 3 are formed without undergoing compression.

The roller 4 is a roller having a plurality of recesses 4a formed on its peripheral surface. The roller 4 can be produced by, for example, forming the recesses 4a on a roller for forming recesses made of one or two or more metallic materials selected from the group consisting of various metals and alloys, preferably made of stainless steel, iron hardened steel, and the like.

On the peripheral surface of the roller for forming recesses, a coating layer containing a cemented carbide or an alloy tool steel may be provided. The formation of such a coating layer finally provides the roller 4 with an increased surface hardness, reducing the variation in the shape of the projections 3 to be formed in the process of compression of the metallic foil 10 for current collector.

Alternatively, on the peripheral surface of the roller for forming recesses, a coating layer containing a cemented carbide or chromium oxide may be provided. Such a coating layer has an effect of reducing the resistance such as frictional force and stress produced under compression. For this reason, the use of the roller 4 produced from the roller for forming recesses with such a coating layer provided thereon, the stress produced between the roller 4 and the metallic foil 10 for current collector in the process of compression is reduced. As a result, the releasability of the current collector 1 from the roller 4 after the process of compression is improved. This is industrially advantageous in that the process management is simplified and the defect rate is reduced. It should be noted that since such a coating layer is fixedly bonded to the roller for forming recesses, it is unlikely that the coating layer is exfoliated after repeated use. This is another industrially advantageous point.

In addition, on the surface of the coating layer containing a cemented carbide or chromium oxide, a protective layer containing an amorphous carbon material may be provided. This finally provides the roller 4 with a further increased surface hardness and renders the effects of reducing the resistance between the roller 4 and the metallic foil 10 for current collector produced in the process of compression and improving the releasability of the current collector 1 from the roller 4 after the process of compression more notable.

The above-described various coating layers and protection layers are preferably formed by a vapor phase growth method, such as a physical vapor phase growth method utilizing sputtering, a physical vapor phase growth method utilizing ion injection, a chemical vapor phase growth method utilizing heat vapor deposition, and a chemical vapor phase growth method utilizing plasma vapor deposition. By doing this, the releasability from the roller 4 of the current collector 1 after the process of compression can be improved.

Alternatively, on the peripheral surface of the roller for forming recesses, a coating layer made of ceramic such as tungsten carbide (WC) and titanium nitride (TiN) may be provided. This finally provides the roller 4 with an increased surface hardness, reducing the variation in the shape of the projections 3 to be formed by plastic deformation without undergoing compression.

In the present invention, the recesses 4a may be formed on the above-described various coating layers or protection layers.

The recesses 4a can be formed by, for example, etching, sandblasting, arc machining, laser machining, and the like. Among these, the laser machining is preferred. According to the laser machining, it is possible to form a minute recesses 4a having a size of several μm order and an arrangement pattern of the recesses 4a in an almost exact manner. Examples of the laser used for the laser machining include a carbonic acid gas laser, a YAG laser, an excimer laser, and the like. Among these, the YAG laser is preferred. It should be noted that the laser machining causes the rim of the opening of the recesses 4a on the peripheral surface of the roller 4 to bulge. Even when the roller 4 is used without removing the bulge, the current collector 1 is obtained. Alternatively, the roller 4 may be used after the bulge is removed by grinding and the like.

The arrangement pattern of the recesses 4a on the peripheral surface of the roller 4 in this embodiment is described below. As shown in FIG. 5(b), a plurality of the recesses 4a are aligned in a row so as to be spaced apart from one another at a pitch Pa in the longitudinal direction of the roller 4. A row of recesses is referred to as one row unit 7. A plurality of the row units 7 are arranged in the circumference direction of the roller 4 at a pitch Pb. The pitch Pa and the pitch Pb may be set as desired. Here, in the circumference direction of the roller 4, one row unit 7 and another row unit 7 adjacent thereto are staggered from each other in the longitudinal direction of the roller 4. The staggered distance between the recesses 4a in the longitudinal direction is 0.5 Pa in this embodiment, but not limited thereto and may be set as desired. Further, the shape of the opening of the recesses 4a on the peripheral surface of the roller 4 is approximately circular in this embodiment, but is not limited thereto and may be, for example, approximately elliptic, approximately rectangular, approximately rhombic, approximately square, approximately regular-hexagonal, approximately regular-octagonal, and the like.

The cross section of each of the recesses 4a in a direction perpendicular to the surface of the roller 4 preferably has a tapered shape in which the width of the cross section in a direction parallel to the peripheral surface of the roller 4 gradually narrows from the peripheral surface of the roller 4 toward the bottom of the recess 4a. This can improve the releasability from the roller 4 of the current collector 1 after the process of compression is completed.

On the peripheral surface of the roller 4 and the surfaces of the recesses 4a facing the internal spaces thereof, one or two or more layers selected from a coating layer containing a cemented carbide, a coating layer containing an alloy tool steel, a coating layer containing chromium oxide, a protective layer containing an amorphous carbon material, and the like may be formed. This provides the same effect as obtained when these coating layers and protective layers are formed on the roller for forming recesses. Moreover, forming these coating layers and protective layers by the same method as described above such as a physical vapor phase growth method, a chemical vapor phase growth method, and the like provides the same effect as described above. According to these vapor phase growth methods, the coating layer and the protective layer can be formed uniformly also on the surfaces of the recesses 4a facing the internal spaces thereof. Further, since the material such as a cemented carbide contains cobalt as a binder, in the case where the metallic foil 10 for current collector contains copper, adhesion of copper to the peripheral surface of the roller 4 and the internal surfaces of the recesses 4a is effectively prevented because of high affinity between copper and cobalt.

On the peripheral surface of the roller 4 and the surfaces of the recesses 4a facing the internal spaces thereof, a coating layer made of ceramic, such as tungsten carbide (WC) and titanium nitride (TiN), may be formed. This provides the roller 4 with an improved surface hardness, resulting in little or no variation in the shape of the projections 3 formed by plastic deformation associated with compression.

As the roller 5, it is possible to use a roller with a smooth or flat peripheral surface and preferably a metallic roller with a smooth or flat peripheral surface.

The contact pressure between the rollers 4 and 5 is not particularly limited, but preferably about 8 kN to 15 kN per 1 cm of the metallic foil 10 for current collector.

In addition, in the process of compression of metallic foil 10 for current collector by the processing means 37, a lubricant may be applied to at least either one of the roller 4 and the metallic foil 10 for current collector. The lubricant is applied onto the peripheral surface of the roller 4 or the surface of the metallic foil 10 for current collector, and dried. This reduces the resistance between the roller 4 and the metallic foil 10 for current collector produced in the process of compression and further improves the releasability from the roller 4 of the current collector 1. The lubricant preferably contains a fatty acid. Among fatty acids, a saturated fatty acid is preferred, and myristic acid is particularly preferred. It is preferable to use the fatty acid in the form of solution. As a solvent to dissolve the fatty acid therein, a solvent that can dissolve the fatty acid and is easily volatile upon drying is preferred. For example, a solvent with low boiling point, such as methanol and ethanol may be used. Applying and drying a fatty acid can further reduce the resistance, particularly the frictional force, produced in the process of compression and prevent the metallic foil 10 for current collector from being stretched excessively in its longitudinal direction, allowing the projections 3 maintaining almost the same original crystal structure of the metallic foil 10 for current collector to be formed in a stable manner. As a result, the separation of the projections 3 from the base 2 is effectively suppressed.

The partial plastic deformation of the metallic foil 10 for current collector by the processing means 37 is described with reference to FIG. 1 and FIG. 2. FIG. 1(a) is a longitudinal cross-sectional view showing the state of the metallic foil 10 for current collector immediately after fed to the press nip 6 in the processing means 37. FIG. 1(b) is a longitudinal cross-sectional view showing the state in which plastic deformation proceeds on one surface of the metallic foil 10 for current collector in the press nip 6. FIG. 1(c) is a longitudinal cross-sectional view of the current collector 1 after passed through the press nip 6.

FIG. 2 shows how the plastic deformation as shown in FIG. 1(b) proceeds step by step in three stages.

In the step shown in FIG. 1(a), the metallic foil 10 for current collector has a film thickness t₀ at the entrance of the press nips 6. The metallic foil 10 for current collector is pressed while being in contact with the surfaces of the rollers 4 and 5.

In the step shown in FIG. 1(b), the metallic foil 10 for current collector is pressed in the direction of its thickness. The surface of the metallic foil 10 for current collector includes a non-contact surface 4b to be opposite to each recess 4a of the roller 4 and a contact surface 4c to be in contact with the flat portion of the peripheral surface of the roller 4, the contact surface 4c surrounding the non-contact surface 4b. The contact surface 4c is compressed in its thickness direction to form the base 2. The thickness of the base 2 is t₁. The thickness t₁ is smaller than t₀. On the other hand, the non-contact surface 4b, which is not pressed, undergoes plastic deformation as the compression of the contact surface 4c proceeds. As a result, the non-contact surface 4b is pushed up in the space of the recess 4a toward the bottom of the recess 4a, to form the projection 3. In other words, the projection 3 is formed without undergoing compression but by plastic deformation associated with compression. The non-contact surface 4b becomes the end surface of the projection 3. Since the end surface of the projection 3 is not compressed at all, the surface roughness thereof is approximately equal to that of the original surface of the metallic foil 10 for current collector.

The progress of plastic deformation shown in FIG. 1(b) is described in more detail with reference to FIG. 2.

In the step shown in FIG. 2(a), the metallic foil 10 for current collector is fed to the press nip 6. At this time, the metallic foil 10 for current collector has a film thickness t₀. In the portion 4b opposite to the recess 4a of the roller 4 of the metallic foil 10 for current collector, stress is applied from the directions indicated by arrows 11a and 11b, namely, from the inside of the metallic foil 10 for current collector toward the recess 4a. This initiates plastic deformation in the opposite portion 4b.

In the step shown in FIG. 2(b), as the plastic deformation of the non-contact surface 4b proceeds, the non-contact surface 4b protrudes toward the bottom of the recess 4a to form a projection 3x. The volume of the projection 3x is about 50% of the volume of the internal space of the recess 4a. Since the end surface of the projection 3x does not undergo compression, the surface condition thereof is approximately equal to that of the original surface of the metallic foil 10 for current collector. To the projection 3x, stresses 12a and 12b are applied, the stresses further pushing the projection 3x toward the bottom of the recess 4a. This allows the plastic deformation to further proceed along the inner wall of the recess 4a.

In the step shown in FIG. 2(c), the plastic deformation of the opposite portion 4b proceeds up to the limit of the volume of the internal space of the recess 4a to form the projection 3. The current collector 1 is thus obtained.

It should be noted that air is present inside the recess 4a. As such, as the plastic deformation of the opposite portion 4b proceeds, the air remains trapped in the internal space of the recess 4a and compressed, producing stress applied to the projection 3 in the directions indicated by the arrows 13a, 13b and 14. With such stress being intensified, the base 2 may be deformed to cause wrinkling, warping, and the like on the current collector 1. Moreover, the shape and size of the projections 3 may become non-uniform.

For the reasons above, it is desirable to perform compression such that the volume of the projections 3 is preferably equal to or less than the volume of the internal space of the recess 4a, and more preferably equal to or less than 85% of the volume of the internal space of the recess 4a. This makes it possible to efficiently form the current collector 1 while the occurrence of defects such as wrinkling, warping, and tearing is suppressed. Further, performing compression such that the volume of the projections 3 is equal to or less than 85% of the volume of the internal space of the recess 4a produces an accompanying effect that the projections 3 can be formed such that the end surfaces of the projections 3 have an approximately equal surface roughness of the original surface of the metallic foil 10 for current collector. Consequently, the separation of the active material from the current collector 1 is suppressed in the steps of forming an electrode by allowing an active material layer to be carried on the surfaces of the projections 3, slitting the electrode into a predetermined width, and other steps.

A further description with reference to FIG. 1 is given below. In the step shown in FIG. 1(c), the projection 3 is formed without undergoing compression. As such, the end surfaces of the projection 3 is free of distortion in the extending direction of the projection 3, and the same surface condition (surface roughness) and the surface accuracy as those of the metallic foil 10 for current collector are maintained. The side face of the projection 3 has a surface condition similar to that of the metallic foil 10 for current collector. On the other hand, having compressed, a depression 2a present between adjacent projections 3 has a surface condition different from that of the metallic foil 10 for current collector. The maximum thickness t₂ of the current collector 1 is a distance from the surface with no projection 3 formed thereon to the end surface of the projection 3 in the thickness direction of the current collector 1. The maximum thickness t₂ of the current collector 1 is larger than the thickness t₀ of the metallic foil 10 for current collector. Here, the relationship between the thickness t₀ and the maximum thickness t₂ can be adjusted by, for example, appropriately selecting the pressure applied at the press nip 6.

In the current collector 1 provided by the roller method, no interface between the base 2 and the projections 3 exists but at least one continuous region extending from the base 2 to the projections 3 exists, the region having almost the same crystal state. The observation of the cross section of the current collector 1 in its thickness direction under an electron microscope reveals that a region having almost the same crystal state exists in at least part of the cross section, the region covering both the base and the projections 3 continuously. Insofar as observed under an electron microscope, the crystal state in this region does not indicate the presence of joints. With such a configuration, the separation of the projections 3 from the base 2, and further the exfoliation of the active material layer from the projections 3 are effectively suppressed.

A further description with reference to FIG. 3 is given below. The current collector winding-up means 38 is specifically a current collector winding-up roller. The current collector winding-up roller is axially supported by a supporting means (not shown) in such a manner that the roller is rotatable around the axis. The current collector winding-up roller is rotated by a driving means (not shown). The current collector winding-up roller rotates and winds up the current collector 1 formed by the processing means 37 on the peripheral surface of the roller.

When the current collector production apparatus 35 is used, the metallic foil 10 for current collector is compressed and partial plastic deformation is caused, and thus the current collector 1 including the base 2 and the plurality of projections 3 is produced.

By compressing using the current collector production apparatus 35 configured as above, pressure can be applied linearly on an extremely small area with respect to the surface of the metallic foil 10 for current collector, and therefore a sufficient compression is possible even when the press capacity is comparatively small. Therefore, the size of the current collector production apparatus 35 can be reduced. Moreover, by using the current collector production apparatus 35, industrially advantageously, the projections 3 can be formed continuously on the surface of the band-shaped metallic foil 10 for current collector.

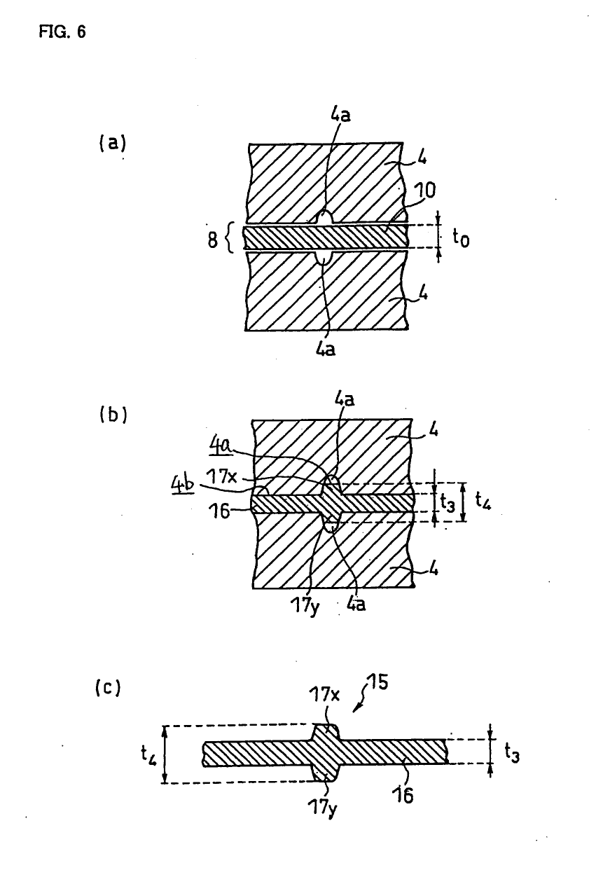

FIG. 6 is a series of longitudinal cross-sectional views schematically showing another production method of a current collector as one embodiment of the present invention. FIG. 6(a) is a longitudinal cross-sectional view showing the state of the metallic foil 10 for current collector immediately after fed to the press nip 6. FIG. 6(b) is a longitudinal cross-sectional view showing the state in which plastic deformation proceeds on the surface of the metallic foil 10 for current collector. FIG. 6(c) is a longitudinal cross-sectional view of the current collector 1 after passed through the press nip 6. The production method of a current collector 15 shown in FIG. 6 is similar to the production method of the current collector 1 shown in FIG. 1. The corresponding parts are denoted by the same reference numerals and thus the description thereof is omitted.

The production method of the current collector 15 as shown in FIG. 6 is characterized in that a pair of processing means having recesses on the surface of both processing means is used and, except this difference, is enabled in the same manner as the production method of the current collector 1 as shown in FIG. 1.

The production method of the current collector 15 is performed by, for example, using a current collector production apparatus having the same configuration as that of the current collector production apparatus 35 shown in FIG. 3 except that the roller 4 is mounted in place of the roller 5. The production method of the current collector 15 is described below with reference to FIG. 6.

In the step shown in FIG. 6(a), the metallic foil 10 for current collector has a film thickness t₀ at the entrance of the press nip 6. The metallic foil 10 for current collector is pressed while being in contact with the peripheral surfaces of the two rollers 4. Each of both surfaces of the metallic foil 10 for current collector in its thickness direction includes the non-contact surface 4b being opposite to each recess 4a of the roller 4 and not being in contact with the peripheral surface of the roller 4 and the contact surface 4c in contact with the peripheral surface of the roller 4. The contact surface 4c surrounds the non-contact surface 4b. Here, the two rollers 4 are disposed in press contact with each other such that the plurality of recesses 4a formed on the peripheral surface of one roller are opposite to those on the peripheral surface of the other roller.

In the step shown in FIG. 6(b), the contact surfaces 4c are compressed to be formed into a base 16. The thickness of the base 16 is t₃. The thickness t₃ is smaller than t₀. On the other hand, the non-contact surfaces 4b, which are not pressed, undergo plastic deformation as the compression of the contact surfaces 4c proceeds. As a result, the non-contact surfaces 4b are pushed up in the spaces of the recesses 4a toward the bottoms of the recesses 4a, to form projections 17x and 17y. In other words, the projections 17x and 17y are formed without undergoing compression but by plastic deformation associated with compression. The non-contact surfaces 4b are little influenced by compression and plastic deformation and become the end surfaces of the projections 17x and 17y, the surface roughness thereof is approximately equal to that of the metallic foil 10 for current collector.

In the step shown in FIG. 6(c), the current collector 15 is obtained. The projections 17x and 17y are formed without undergoing compression. As such, the end surfaces of the projections 17x and 17y are free of distortion in the extending direction of the projections 17x and 17y, and almost the same surface roughness and the face accuracy as those of the metallic foil 10 for current collector are maintained. The side faces of the projections 17x and 17y have a surface condition similar to that of the metallic foil 10 for current collector since the side surfaces are not compressed but are influenced by plastic deformation. On the other hand, having compressed, the bases 16 each present between adjacent projections 17x and 17y have a surface condition different from that of the metallic foil 10 for current collector. The maximum thickness t₄ of the current collector 15 is a distance between the flat end surfaces of the projections 17x and 17y formed on both surfaces of the current collector 15 in its thickness direction. The maximum thickness t₄ of the current collector 15 is larger than the original thickness t₀ of the metallic foil 10 for current collector. Here, the relationship between the thickness t₀ and the maximum thickness t₄ can be adjusted by, for example, appropriately selecting the pressure applied at the press nip 6.

### [Current Collector for Non-Aqueous Electrolyte Secondary Battery]

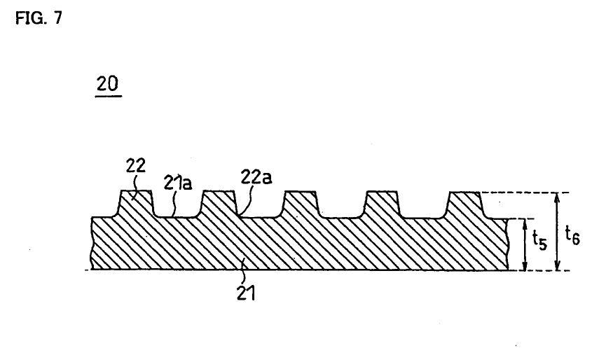

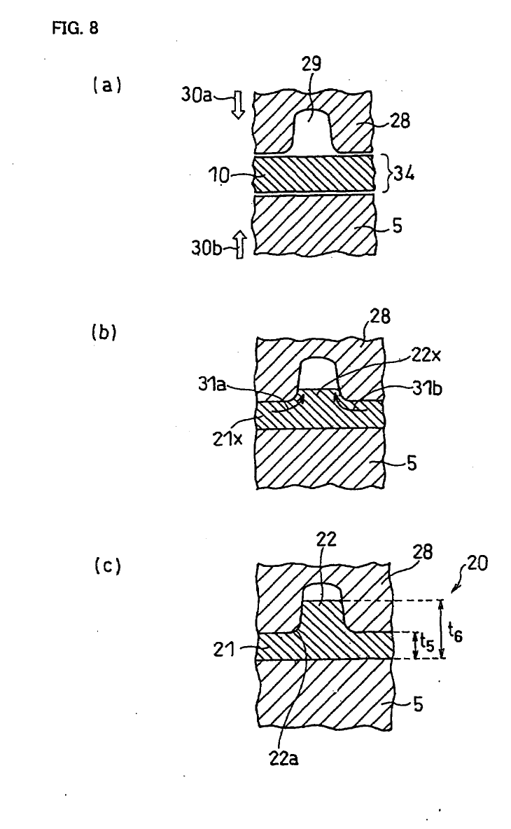

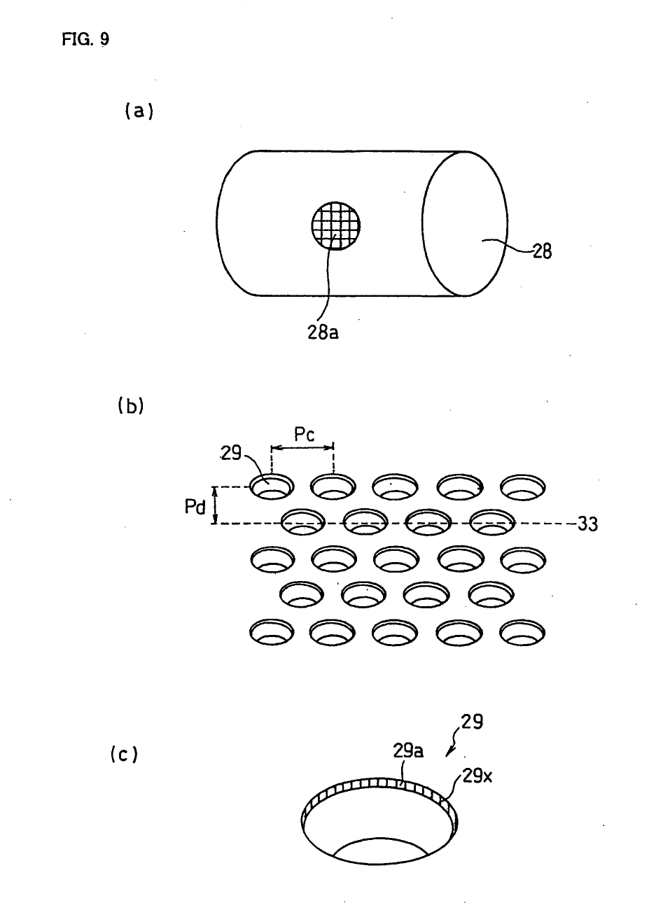

FIG. 7 is a longitudinal cross-sectional view schematically showing a current collector 20 for a non-aqueous electrolyte secondary battery being another embodiment of the present invention. FIG. 8 is a series of longitudinal cross-sectional views schematically showing a production method of the current collector 20 for a non-aqueous electrolyte secondary battery shown in FIG. 7. FIG. 8(a) is a longitudinal section view showing a state of the metallic foil 20 for a current collector immediately after fed to a press nip 6. FIG. 8(b) is a longitudinal cross-sectional view showing a state in which plastic deformation proceeds on the surface of the metallic foil 10 for current collector in the press nip 6. FIG. 8(c) is a longitudinal cross-sectional view of the current collector 20 after passed through the press nip 6. FIG. 9 is a set of drawings schematically showing a configuration of a roller 28 used in the production method shown in FIG. 8. FIG. 9(a) is a perspective view showing an appearance of the roller 28. FIG. 9(b) is an enlarged perspective view showing a surface region 28a of the roller 28. FIG. 9(c) is an enlarged perspective view showing a recess 29 formed on the peripheral surface of the roller 28.

The current collector 20 includes a base 21 and a plurality of projections 22.

The current collector 20 is produced by compressing the metallic foil 10 for current collector using a pair of processing means to cause partial plastic deformation, as in the case of the current collector 1. Compression is provided on one surface of the metallic foil 10 for current collector. A detailed description about compression is given later.

In the case of using the current collector 20 as a negative electrode current collector, the current collector 20 is composed of the same material as used for the metallic foil 10 for current collector in the case of using the current collector 1 as a negative electrode current collector. In the case of using the current collector 20 as a positive electrode current collector, the current collector 20 is composed of the same material as used for the metallic foil 10 for current collector in the case of using the current collector 1 as a positive electrode current collector.

The base 21 is formed into a sheet whose cross section in its thickness direction is approximately square.

The thickness of the base 21 is t₅. The thickness t₅ is not particularly limited, but preferably 5 μm to 100 μm and more preferably 8 to 35 μm. When the thickness of the base 21 is less than 5 μm, the mechanical strength of the current collector 20 may become insufficient. This will consequently reduce the ease of handling of the current collector 20 during production of the electrode and easily cause the rupture of the electrode during charging of a battery, and the like. When the thickness of the base 21 exceeds 100 μm, although the mechanical strength of the current collector 20 is ensured, the ratio of the volume of the current collector 20 to that of the electrode is increased, and consequently the capacity of the battery may not be improved sufficiently.

A surface 21a of the base 21 undergoes compression as described later and therefore has a surface roughness different from that of the metallic foil 10 for current collector.

The plurality of projections 22 are formed on one surface of the base 21 in its thickness direction. The projections 22 are formed so as to extend outwardly from the surface of the base 21. The projections 22 have a function of, for example, carrying an active material layer on at least part of their surfaces.

The projections 22 are formed without undergoing compression but by plastic deformation associated with compression of the base 21. The end surfaces of the projections 22 are little influenced by compression and plastic deformation, and therefore have a surface roughness approximately equal to the original surface roughness of the metallic foil 10 for current collector. The end surfaces of the projections 22 are flat surfaces furthest away from the base 21 of the projections 22 in the extending direction or the protruding direction of the projections 22.

Two adjacent projections 22 are formed so as to be spaced apart from each other. Accordingly, in the cross section of the current collector 20 in its thickness direction shown in FIG. 7, the surface 21a of the base 21 exists as a depression between two adjacent projections 22.

The cross section of each of the projections 22 in the direction of the thickness of the current collector 20 (hereinafter simply referred to as the “cross section of the projections 22”) has a tapered shape. Specifically, the cross section of the projections 22 has a tapered shape in which the width of the cross section in a direction parallel to the surface of the base 21 (hereinafter simply referred to as the “cross sectional width of the projections 22”) is gradually or continuously reduced from the surface of the base 21 along the extending direction of the projections 22. In this embodiment, the cross section of the projections 22 is approximately trapezoidal. Since the projections 22 have a tapered shape, the releasability of the current collector 20 from the roller 28 after the process of compression is improved and the deformation of the projections 22 is prevented, and therefore, the variation in shape of the projections 22 can be minimized.

Although the shape of the projections 22 in this embodiment is of circular truncated cone, no particular limitation is imposed on the shape of the projections 22 as long as the cross section of the projections 22 has a tapered shape. Moreover, the end surfaces of the projections 22 in this embodiment are flat surfaces almost parallel to the surface of the base 21 in the extending direction of the projections 22, but not limited thereto. For example, the end surfaces may be flat surfaces not parallel to the surface of the base 21, or of a hemispherical or dome shape with rough surface, and the like. These shapes are effective in enhancing the bonding strength between the projections 22 and the active material layer.

In FIG. 7, when a perpendicular line is drawn from the line representing the end surfaces of the projections 22 to the line representing the surface of base 21 where no projections 22 are formed, the length of perpendicular line is t₆. The projections 22 are formed so that t₆ is larger than the thickness t₀ of the original metallic foil 10 for current collector. It should be noted that t₆ can be alternatively defined as a maximum thickness of the current collector 20.

A boundary 22a between the base 21 and each of the projections 22 on the surface 21a of the base 21 is formed of a curved surface. Here, the boundary 22a involves an area around the boundary 22a. Since the boundary 22a is formed of a curved surface, if some force acts on the projection 22, the stress can be dispersed, and therefore, the mechanical strength of the current collector 20 is increased. As a result, in the steps of forming the projections 22, allowing an active material to be carried on the projections 22 to form an electrode, and other steps, it is possible to prevent local deflection, deformation and the like from occurring on the current collector 20. Further, in the steps of slitting the electrode into a predetermined width after the production of the electrode and other steps, it is possible to prevent exfoliation, partial separation, and the like of the active material layer from the current collector 20.

As described above, FIG. 8 is a series of longitudinal cross-sectional views for explaining the production method of the current collector 20. In the step shown in FIG. 8(a), compression of the metallic foil 10 for current collector is performed, for example, using a current collector production apparatus having the same configuration as that of the current collector production apparatus 35 shown in FIG. 3 except that the roller 28 shown in FIG. 9 is used in place of the roller 4.

As shown in FIG. 9(a) and FIG. 9(b), the plurality of recesses 29 are formed on the peripheral surface of the roller 28. As shown in FIG. 9(c), in the recesses 29, an opening rim 29a of each of the recesses 29 on the peripheral surface of the roller 28 is formed of a curved surface, and the curved surface has a plurality of grooves 29x. The grooves 29x are formed linearly in a direction from the peripheral surface of the roller 28 toward the bottom of the recess 29. The width of the grooves 29x is not particularly limited, but preferably 1 μm or less. The depth of the grooves 29x is not particularly limited, but preferably 1 μm or less. Here, the depth of the grooves 29x is a length measured in the direction from the surface of the opening rim 29a toward the axis of the roller 28.

By using the roller 28 with the recesses 29 formed thereon in which the opening rim 29a is formed of a curved surface, the stress such as resistance and frictional force produced between the surfaces of the metallic foil 10 for current collector and the roller 28 in the process of compression of the metallic foil 10 for current collector can be reduced, and the releasability of the current collector 20 from the roller 28 after the process of compression is completed can be improved. Further, stress that causes partial plastic deformation on the metallic foil 10 for current collector can be applied mildly and surely, making it possible to form the projections 22 without fail and thus to improve the processability. As a result, it is possible to prevent local deflection, deformation and the like from occurring on the current collector 20 as well as to remarkably reduce the variation in the shape, height, and the like of the projections 22. As a result, the projections 22 having uniform shape and size such as height can be formed without deforming the projections 22.

Moreover, by forming the plurality of grooves 29x on the opening rim 29a, the atmosphere remaining in the internal spaces of the recesses 29, the lubricant applied to the peripheral surface of the roller 28 and/or the surface of the metallic foil 10 for current collector, and the like can be discharged outside from the internal spaces of the recesses 29 through the grooves 29x in the process of compression. As such, in the internal spaces of the recesses 29, the internal resistance acting to inhibit the plastic deformation for forming the projections 22 is reduced. As a result, the plastic deformation for forming the projections 22 proceeds smoothly, the variation in the shape, size, and the like of the projections 22 is reduced, and the local variation in the mechanical strength of the current collector 22 is reduced. This effect is particularly evident when the grooves 29x has a width of 11m or less and the depth of 1 μm or less. When the width or the depth of the grooves 29x is excessively large, although the remaining atmosphere, the lubricant, and the like are well discharged, the plastic deformation for forming the projections 22 may not proceed sufficiently.

The arrangement pattern of the recesses 29 on the peripheral surface of the roller 28 in this embodiment is described below. As shown in FIG. 9(b), a plurality of the recesses 29 are aligned in a row so as to be spaced apart from one another at a pitch Pc in the longitudinal direction of the roller 28. A row of recesses is referred to as one row unit 33. A plurality of the row units 33 are arranged in the circumference direction of the roller 28 at a pitch Pd. The pitch Pc and the pitch Pd may be set as desired. Here, in the circumference direction of the roller 28, one row unit 33 and another row unit 33 adjacent thereto are staggered from each other in the longitudinal direction of the roller 28. The staggered distance between the recesses 29 in the longitudinal direction is 0.5Pc in this embodiment, but not limited thereto and may be set as desired. Further, the shape of the opening of the recesses 29 on the peripheral surface of the roller 28 is approximately circular in this embodiment, but not limited thereto and may be, for example, approximately elliptic, approximately rectangular, approximately rhombic, approximately square, approximately regular-hexagonal, approximately regular-octagonal, and the like.

The roller 28 can be produced by machining a roller for forming recesses as used in the production of the roller 4 by, for example, etching, sandblasting, arc machining, laser machining, and the like. For the laser machining, the method as used in the case of producing the roller 4 is used.

In the case where the recesses are formed on a roller for forming recesses by laser machining, a bulge (not shown) is produced on the opening rim 29a of the roller for forming recesses. The recess 29 whose opening rims 29a are formed of a curved surface is obtained by removing this bulge, and thus the roller 28 is obtained. Preferably, the bulge is removed by grinding with diamond particles. Preferably, the diamond particles are larger in size than the minimum size of the recesses 29. More preferably, the diamond particles have an average particle size of 30 μm or more and less than 53 μm. Here, the size of the recesses 29 means a diameter of the opening of the recesses 29 on the peripheral surface of the roller 28. The use of the diamond particles having such an average particle size allows the opening rims 29a to have a curved surface having a large radius of curvature and more effectively prevents the projections 22 from being exfoliated from the base 21. Moreover, the diamond particles are prevented from entering and staying in the interior of the recesses 29.

The grinding with diamond particles can be performed in the same manner as the general grinding method as long as the diamond particles are used as abrasive particles or grinding particles. Normally, the diamond particles are placed on a surface to be ground, and then the grinding is performed in a grinder provided with a grinding pad, while a grinding medium such as water is being supplied.

The grooves 29x are formed on the surface of the opening rim 29a by grinding with diamond particles each having an average particle size of 5 μm or less. As a result, the plurality of grooves 29x each having a width of 1 μm or less and a depth of 1 μm or less are easily formed. The grooves 29x may be formed after the bulge is removed by grinding or while the bulge is being removed by grinding. Here, since the diamond particles used in this process have an extremely small particle size, the diamond particles will not stay in the recesses 29 and easily removed by washing after the formation of the grooves 29x.

On the peripheral surface of the roller 28 thus obtained and the surface facing the internal spaces of the recesses 29, as in the case of the roller 4, one or two or more selected from a coating layer containing a cemented carbide, a coating layer containing an alloy tool, a coating layer containing chromium oxide, a protective layer containing an amorphous carbon material, a coating layer made of ceramic, and the like may be provided. This brings about the same effect as obtained when these coating layers and protective layers are formed on the roller 4.

The roller 28 is disposed such that its peripheral surface is in press contact with the peripheral surface of the roller 5 and its axis is in parallel with the axis of the roller 5, thereby to forms a press nip 34.

In the step shown in FIG. 8(a), the metallic foil 10 for current collector is fed to the press nip 34, and pressures 30a and 30b are applied thereto in the thickness directions of the metallic foil 10 for current collector.

In the step shown in FIG. 8(b), in the surface opposite to the peripheral surface of the roller 28 of the metallic foil 10 for current collector, the contact surface to be in contact with the peripheral surface of the roller 28 is compressed by the pressures 30a and 30b; and the non-contact surfaces not to be in contact with the peripheral surface of the roller 28 and face the recesses 29 are not compressed. The contact surface surrounds the non-contact surfaces. Specifically, the contact surface is compressed so that the thickness in the contact surface becomes smaller than that of the metallic foil 10 for current collector and an elevation 21x to become the base 21 is formed. On the other hand, to the non-contact surface, stresses 31a and 31b are applied along the surface facing the internal space of the recess 29 from around the non-contact surface toward the bottom of the recess 29 as the contact surface is compressed. This allows plastic deformation to occur in the non-contact surface, so that the non-contact surface is elevated toward the bottom of the recess 29 to form a projection 22x. At this time, the boundary between the elevation 21x and the projection 22x becomes a curved surface along the opening rim 29a of the recess 29. At this stage of the compression, the volume of the projection 22x is less than 50% of the volume of the internal space of the recess 29, the pressures are continued to be applied.

In the step shown in FIG. 8(c), the current collector 20 is obtained. In the current collector 20, a boundary 22a between the base 21 and the projection 22 is formed of a curved surface. Preferably, the compression by the roller 28 and the roller 5 is continued until the thickness t₅ of the base 21 becomes smaller than the thickness to of the metallic foil 10 for current collector, and the maximum thickness t₆ of the current collector 20 becomes larger than the thickness t₀ of the metallic foil 10 for current collector. More preferably, the compression is continued until the volume of the projection 22 becomes 50% or more of the volume of the internal space of the recess 29, and desirably 50 to 85%. When less than 50%, the projections 29 are not sufficiently high, and therefore an active material may not be carried thereon smoothly. Moreover, the active material carried thereon may be highly possibly separated from the current collector 20. On the other hand, when more than 85%, the air remaining in the interior of the recesses 29, the vapor of the lubricant, and the like are compressed to increase the internal pressure, and consequently the smooth proceeding of plastic deformation for forming the projections 22 may be inhibited, resulting in variation in the shape of the projections 22.

In the current collector 20, the surface 21a of the base 21 where no projections 22 are formed undergoes compression, and therefore has a surface roughness different from that of the metallic foil 10 for current collector. The end surfaces of the projections 22 are not compressed and little influenced by plastic deformation, and therefore has a surface roughness approximately equal to that of the metallic foil 10 for current collector. The side surfaces of the projections 22 are not compressed but are influenced by plastic deformation, and therefore have a surface roughness similar to that of the metallic foil 10 for current collector. As such, by allowing an active material layer to be carried on the surfaces of the projections 22, preferably on the end surfaces thereof, the separation of the active material layer from the current collector 20 that may occur during repeated charge/discharge cycles can be more effectively prevented.

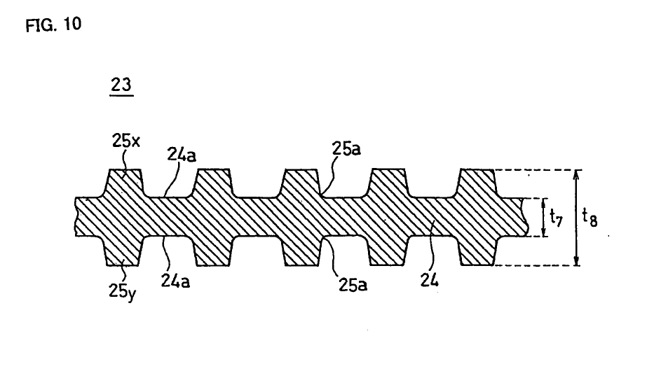

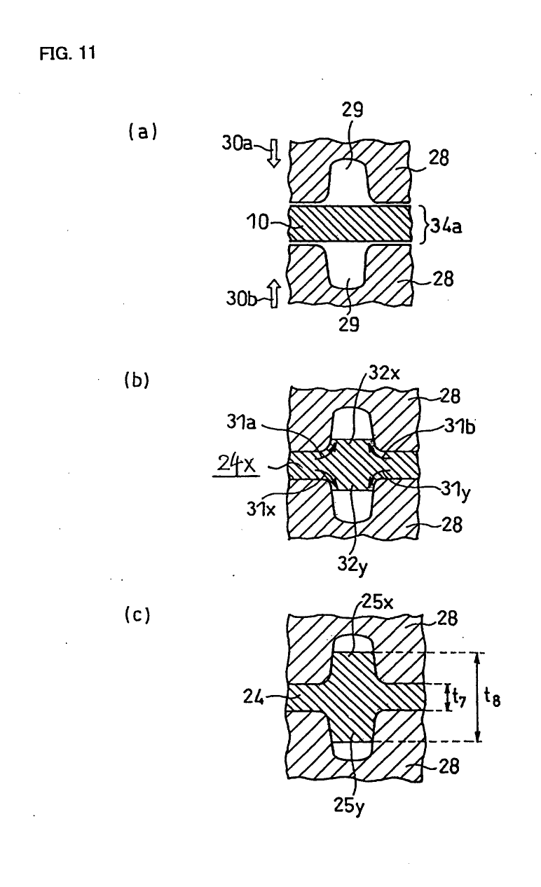

FIG. 10 is a longitudinal cross-sectional view schematically showing a configuration of a current collector 23 for a non-aqueous electrolyte secondary battery of another embodiment. FIG. 11 is a series of longitudinal cross-sectional views schematically showing the production method of the current collector 23 shown in FIG. 10. FIG. 11(a) is a longitudinal cross-sectional views showing the state of the metallic foil 10 for current collector immediately after fed to a press nip 34a. FIG. 11(b) is a longitudinal cross-sectional view showing the state in which plastic deformation proceeds on the surfaces of the metallic foil 10 for current collector in the press nip 34a. FIG. 11(c) is a longitudinal cross-sectional view showing the state of the current collector 23 immediately after formed in the press nip 34a.

The current collector 23 has the same configuration as the current collector 20 except that a plurality of projections 25x and 25y are formed on both surfaces a base 24 in its thickness direction. Specifically, the base 24 is configured similarly to the base 21. The projections 25x and 25y are each configured similarly to the projections 22. The projections 25x are formed so as to extend or protrude outwardly from one surface of the base 24 in its thickness direction. The projections 25y are formed so as to extend or protrude outwardly from the other surface of the base 24 in its thickness direction. The projections 25x and the projections 25y extend in opposite directions.

Further, in the current collector 23, boundaries 25a between the base 24 and the projections 25x and 25y are formed of a curved surface. This provides the same effect as obtained when the boundaries 22a in the current collector 20 are formed of a curved surface.

Furthermore, in the cross section of the current collector 23 in its thickness direction, the lines representing the end surfaces of the projections 25x and 25y are almost parallel to the line representing a surface 24a of the base 24. The end surfaces of the projections 25x and 25y are almost flat without undergoing compression, and therefore have a surface roughness approximately equal to that of the metallic foil 10 for current collector, the metallic foil being a starting material. The side surfaces of the projections 25x and 25y have a surface roughness similar to that of the metallic foil 10 for current collector since the side surfaces are not compressed but are influenced by plastic deformation. For this reason, by allowing an active material layer on the surfaces of the projections 25x and 25y, preferably on the end surfaces thereof, the separation of the active material layer from the current collector 23 during repeated charge/discharge cycles can be more effectively prevented.

Further, in the current collector 23, the thickness t₇ of the base 24 is smaller than the thickness t₀ of the metallic foil 10 for current collector serving as a starting material. The thickness t₈, which is a distance between the end surfaces of the projections 25x and the end surfaces of the projections 25y, is larger than the thickness t₀ of the metallic foil 10 for current collector. The thickness t₈ can be alternatively defined as a maximum thickness of the current collector 23. With such a configuration, the current collector 23 can have a higher mechanical strength and an increased durability.

The current collector 23 can be produced, for example, by using a current collector production apparatus having the same configuration as that of the current collector production apparatus 35 shown in FIG. 3 except that two rollers 28 are used in place of the rollers 4 and 5.

As described above, FIG. 11 is a series of longitudinal cross-sectional views for explaining the production method of the current collector 23.

In the step shown in FIG. 11(a), the metallic foil 10 for current collector is fed to the press nip 34a formed by disposing the two rollers 28 such that the peripheral surfaces of the two rollers are in press contact with each other and the axes thereof are in parallel with each other. The pressures 30a and 30b are applied to the metallic foil 10 for current collector in its thickness direction.

In the step shown in FIG. 11(b), in the surfaces of the metallic foil 10 for current collector that are opposite to the peripheral surfaces of the rollers 28, the contact surfaces to be in contact with the peripheral surfaces of the rollers 28 are compressed by the pressures 30a and 30b. The non-contact surfaces not to be in contact with the peripheral surfaces of the rollers 28 and face the recesses 29 are not compressed but undergo plastic deformation that occurs in association with compression of the contact surfaces. The contact surfaces surround the non-contact surfaces. Specifically, the contact surfaces are compressed so that the thickness in the contact surfaces becomes smaller than that of the metallic foil 10 for current collector and elevations 24x to become the source of the base 24 are formed. On the other hand, to the non-contact surfaces, the stresses 31a, 31b, 31x and 31y are applied along the surfaces facing the internal spaces of the recesses 29 from around the non-contact surfaces toward the bottoms of the recesses 29 as the contact surfaces are compressed. This allows plastic deformation to proceed in the non-contact surfaces, so that the non-contact surfaces are elevated toward the bottoms of the recesses 29 to form projections 32x and 32y. At this time, the boundaries between the elevations 24x and the projections 32x and 32y become a curved surface along the opening rim 29a of the recesses 29. At this stage of the compression, the volumes of the projections 32x and 32y are less than 50% of the internal volume of the recess 29, the pressures are continued to be applied.

In the step shown in FIG. 11(c), the current collector 23 is obtained. In the current collector 23, boundaries 25a between the base 24 and the projections 25x and 25y are each formed of a curved surface. Preferably, the compression by the two rollers 28 is continued until the thickness t₇ of the base 24 becomes smaller than the thickness to of the metallic foil 10 for current collector, and the maximum thickness t₈ of the current collector 23 becomes larger than the thickness t₀ of the metallic foil 10 for current collector. More preferably, the compression is continued until the volume of the projections 25x and 25y becomes 50% or more of the volume of the internal space of the recess 29, and desirably 50 to 85%. When less than 50%, the projections 29 are not sufficiently high, and therefore the active material may not be carried thereon smoothly. Moreover, the active material carried thereon may be highly possibly separated from the current collector 20. On the other hand, when more than 85%, the air remaining in the interior of the recess 29, the vapor of the lubricant, and the like are compressed to increase the internal pressure, which may result in the variation in the shape of the projections 25x and 25y.

In the present embodiments, the current collector production apparatus 35 shown in FIG. 3 or a current collector production apparatus similar thereto are used in producing the current collectors 1, 15, 20 and 23 of the present invention, but not limited thereto. For example, dies, such as a die set, with a recess shaped correspondingly to the shape of the projection formed thereon may be used. By sandwiching and pressing the metallic foil 10 for current collector in the thickness direction thereof with the dies, the compression of the present invention can be performed on the metallic foil 10 for current collector. In such a manner also, the current collectors 1, 15, 20 and 23 of the present invention can be produced.

The current collector obtained by the production method of the present invention is suitably used, but not limited thereto, as a current collector for a non-aqueous electrolyte secondary battery, and may be used as a current collector for a secondary battery other than non-aqueous electrolyte secondary batteries or for a primary battery such as a lithium primary battery.

### [Production Method of Electrode for Non-Aqueous Electrolyte Secondary Battery]

The production method of an electrode for a non-aqueous electrolyte secondary battery according to the present invention may be the same as the conventional production method of a current collector except that the current collector produced in accordance with the production method of the present invention is used as a current collector. For example, an electrode material mixture slurry is applied onto the surface of the current collector produced in accordance with the production method of the present invention, and then dried, thereby to allow an active material layer to be carried on the surface of the current collector. Alternatively, an active material layer in the form of thin film may be formed on the surface of the current collector.

The projections of the current collector obtained in accordance with the production method of the present invention are formed without undergoing compression. The surfaces of the projections are not influenced by compression, and in particular, the end surfaces of the projections are little influenced by plastic deformation and, therefore, have little or no distortion by processing. As such, when an active material layer in the form of thin film is formed on the surface of the current collector obtained in accordance with the production method of the present invention, a thin film with high precision and uniform thickness can be formed. Moreover, since the surfaces of the projections, particularly the end surfaces of the projections maintain the surface roughness of the metallic foil before processing, the adhesion between the thin film being an active material layer and the surface of the current collector is improved. This effect is particularly evident when an active material layer is formed on the current collector in which the boundaries between the base and the projections are formed of a curved surface.

The electrode material mixture slurry includes a positive electrode material slurry and a negative electrode material slurry. First, the production of a positive electrode including a positive electrode material mixture slurry is described. The positive electrode material mixture slurry contains a positive electrode active material and a solvent and includes, as needed, a binder for positive electrode, a conductive material, and the like.

As the positive electrode active material, a commonly used one in the field of non-aqueous electrolyte secondary batteries may be used, examples of which include composite oxides, such as lithium cobalt oxide and modified materials thereof (materials obtained by dissolving aluminum or magnesium in lithium cobalt oxide, and the like); lithium nickel oxide and modified materials thereof (materials obtained by partially replacing nickel with cobalt); and lithium manganese oxide and modified materials thereof. These positive electrode active materials may be used alone or in combination of two or more.

As the binder for positive electrode, a commonly used one in the field of non-aqueous electrolyte secondary batteries may be used, examples of which include polyvinylidene fluoride (PVdF), modified polyvinylidene fluoride, polytetrafluoroethylene (PTFE), rubber particle binders having an acrylate unit, and the like. Such a binder for positive electrode may be used together with an acrylate monomer or an acrylate oligomer with a reactive functional group introduced therein. These binders for positive electrode may be used alone or in combination of two or more.

As the conductive material, a commonly used one in the field of non-aqueous electrolyte secondary batteries may be used, examples of which include carbon blacks such as acetylene black, Ketjen black, channel black, furnace black, lamp black, and thermal black; various graphites; and the like. These conductive materials may be used alone or in combination of two or more.

The positive electrode material mixture slurry is prepared by, for example, dispersing the positive electrode active material, and as needed, the binder for positive electrode, a conductive material, and the like into an appropriate dispersion medium, and as needed, adjusting the viscosity so as to be suitable for application to the current collector. As the dispersion medium, water, an organic solvent such as 2-methyl-N-pyrrolidone, or the like may be used. In dispersing a solid matter such as the positive electrode active material into a solvent, for example, a conventional dispersion apparatus such as a planetary mixer may be used.

This positive electrode material mixture slurry is applied onto one or both surfaces of the positive electrode current collector and dried, and as needed, the thickness is adjusted to a predetermined thickness by pressing, whereby a positive electrode plate is obtained. The thickness of the positive electrode current collector is not particularly limited, but preferably 5 to 30 μm. In the application of the positive electrode material mixture slurry onto the positive electrode current collector, for example, a conventional application apparatus such as a die coater may be used. The drying temperature is selected appropriately according to the type of the solvent.

Next, the production of a negative electrode including a negative electrode material mixture slurry is described. The negative electrode material mixture slurry contains a negative electrode active material and a dispersion medium and includes, as needed, a binder for negative electrode, a conductive material, and the like.

As the negative electrode active material, a commonly used one in the field of non-aqueous electrolyte secondary batteries may be used, examples of which include graphite materials such as various natural graphites and artificial graphites; silicon-based composite materials such as silicide; various alloy materials; and the like. These negative electrode active materials may be used alone or in combination of two or more.

As the binder for negative electrode, a commonly used one in the field of non-aqueous electrolyte secondary batteries may be used, examples of which include PVDF and modified PVDF; styrene-butadiene copolymer rubber (SBR) particles and modified SBR; cellulose-based resins, such as carboxymethylcellulose (CMC); and the like. These binders for negative electrode may be used alone or in combination of two or more. In particular, a mixture of SBR particles and a cellulose-based resin, a mixture obtained by adding a small amount of cellulose-based resin into SBR particles, and the like are preferred. The use of such a mixture improves, for example, the lithium ion acceptability, and the like.

Examples of the conductive material are the same as those used for the positive electrode.

The negative electrode material mixture slurry can be prepared in the same manner as the positive electrode material mixture slurry. As the dispersion medium in which the negative electrode active material is dispersed, for example, water, an organic solvent such as 2-methyl-N-pyrrolidone, or the like may be used.

This negative electrode material mixture slurry is applied onto one or both surfaces of the negative electrode current collector and dried, and as needed, the thickness is adjusted to a predetermined thickness by pressing, whereby a negative electrode plate is obtained. The thickness of the negative electrode current collector is not particularly limited, but preferably 5 to 25 μm. In the application of the negative electrode material mixture slurry onto the negative electrode current collector, for example, a conventional application apparatus such as a die coater may be used. The drying temperature is selected appropriately according to the type of the solvent.

In forming an active material layer in the form of thin film on the surface of the current collector, a vacuum processing is suitably used. Among the examples of the vacuum processing, a vapor deposition method, a sputtering method, a chemical vapor deposition growth method (CVD), and the like are preferred. For example, in the vapor deposition of an active material on the surface of the current collector, a conventional vapor deposition apparatus is used. According to the vacuum vapor deposition, the active material layer can be selectively formed on a predetermined portion of the current collector. The vapor deposition apparatus is not particularly limited, but a vapor deposition apparatus provided with an electron beam heating means with which an active material is heated and vaporized to be deposited on the surface of the current collector is preferred. Such a vapor deposition apparatus is commercially available from, for example, ULVAC, Inc. In the case of vapor deposition, only an active material is mainly vapor-deposited.

As an active material to be formed by vapor deposition, the negative electrode active material is preferred. Examples of the negative electrode active material include Si, Sn, Ge, Al, and an alloy containing one or more of these; an oxide, such as SiOₓ and SnOₓ; a sulfide, such as SiSₓ and SnS; and the like. The negative electrode active material layer is formed in a columnar shape on the surface of the negative electrode current collector, preferably on the end surfaces of the projections of the negative electrode current collector. The negative electrode active material layer preferably contains an amorphous or low crystalline negative electrode active material.

The thickness of the active material layer formed on the surface of the current collector, preferably on the surfaces of the projections, more preferably on the end surfaces of the projections may be selected appropriately according to various conditions, such as the type of the active material, the forming method of the active material layer, the characteristics required for a finally produced non-aqueous electrolyte secondary battery, and the use of the battery, but is preferably 5 to 30 μm and more preferably 10 to 25 μm.

[Non-Aqueous Electrolyte Secondary Battery]

The non-aqueous electrolyte secondary battery of the present invention includes the electrode of the present invention, a counter electrode thereof, and a lithium ion conductive non-aqueous electrolyte. In other words, the non-aqueous electrolyte secondary battery of the present invention is a non-aqueous electrolyte lithium secondary battery. When the non-aqueous electrolyte secondary battery of the present invention includes the electrode of the present invention as the negative electrode, no particular limitation is imposed on the structure of the positive electrode. Conversely, when the non-aqueous electrolyte secondary battery of the present invention includes the electrode of the present invention as the positive electrode, no particular limitation is imposed on the structure of the negative electrode. It should be noted that the electrode of the present invention is preferably used as the negative electrode.

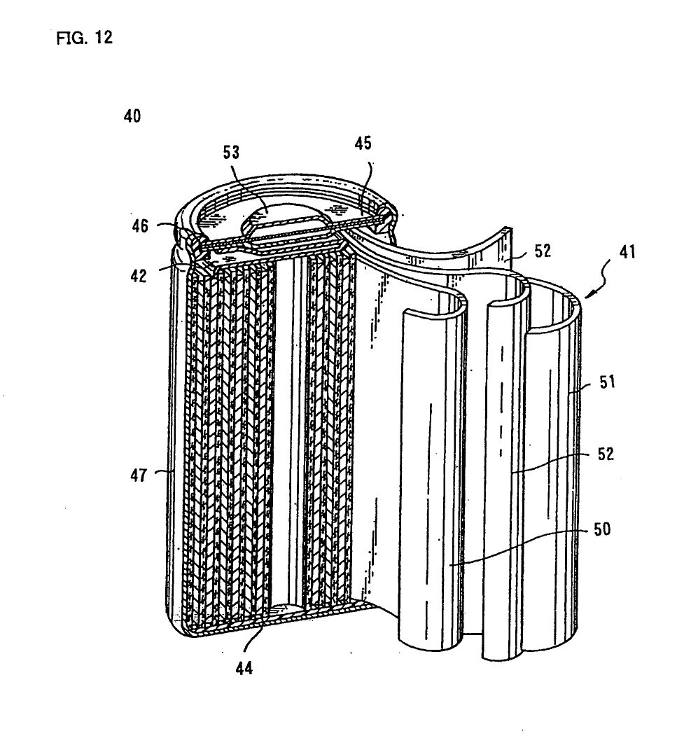

FIG. 12 is a partially exploded perspective view schematically showing a configuration of a non-aqueous electrolyte secondary battery 40 being one embodiment of the present invention. The non-aqueous electrolyte secondary battery 40 includes an electrode plate group 41, a positive electrode lead 42, a negative electrode lead (not shown), an insulating plate 44, a sealing plate 45, a gasket 46, and a battery case 47.

The electrode plate group 41 includes a positive electrode 50, a negative electrode 51, and a separator 52, in which the positive electrode 50, the separator 52, the negative electrode 51, and the separator 52 are laminated in this order and wound spirally. The electrode plate group 41 includes an electrolyte (not shown).

When the positive electrode 50 is the electrode of the present invention or when the negative electrode 51 is the electrode of the present invention, the electrode includes a positive electrode current collector (not shown) and a positive electrode active material layer (not shown).

As the positive electrode current collector, a commonly used one in this field may be used, examples of which include foils made of aluminum, an aluminum alloy, stainless steel, titanium, and the like; non-woven fabrics; and the like. The thickness of the positive electrode current collector is not particularly limited, but preferably 5 μm to 30 μm.

The positive electrode active material layer is formed on one or both surfaces of the positive electrode current collector in its thickness direction and contains a positive electrode active material and, as needed, a conductive material and a binder. Examples of the positive electrode active material include the lithium-containing transition metal oxides as exemplified above, metal oxides not containing lithium such as MnO₂, and like.

As the conductive material, a commonly used one in this field may be used, examples of which include graphites such as natural graphite and artificial graphite; carbon blacks such as acetylene black, Ketjen black, channel black, furnace black, lamp black, and thermal black; electrically conductive fibers such as carbon fiber and metallic fiber; carbon fluoride powder; metallic powders such as aluminum powder; electrically conductive whiskers such as zinc oxide whisker and potassium titanate whisker; electrically conductive metal oxides such as titanium oxide; electrically conductive organic materials such as phenylene derivatives; and the like.

Examples of the binder include polyvinylidene fluoride (PVDF), polytetrafluoroethylenes, polyethylenes, polypropylenes, aramid resins, polyamides, polyimides, polyamide-imides, polyacrylonitriles, polyacrylic acids, polymethyl acrylates, polyethyl acrylates, polyhexyl acrylates, polymethacrylic acids, polymethyl methacrylates, polyethyl methacrylates, polyhexyl methacrylates, polyvinyl acetates, polyvinylpyrrolidones, polyethers, polyethersulfones, hexafluoropolypropylenes, styrene-butadiene rubbers, carboxymethylcellulose, rubber particle binders having an acrylate unit, and the like. Additional examples of the binder include, copolymers composed of two or more monomer compounds selected from the group consisting of tetrafluoroethylenes, hexafluoroethylenes, hexafluoropropylenes, perfluoroalkyl vinyl ethers, vinylidene fluorides, chlorotrifluoroethylenes, ethylenes, propylenes, pentafluoropropylenes, fluoromethyl vinyl ethers, acrylic acids, hexadienes, acrylate monomers having a reactive functional group, acrylate oligomers having a reactive functional group, and the like.

The positive electrode 50 is produced, for example, in the following manner. First, a positive electrode material mixture slurry is prepared by mixing and dispersing a positive electrode active material, and, as needed, a conductive material, a binder, and the like into a dispersion medium. As the dispersion medium, a commonly used dispersion medium in this field, such as N-methyl-2-pyrrolidone, may be used. In mixing and dispersing a positive electrode active material and other materials into a dispersion medium, for example, a generally used dispersion apparatus such as a planetary mixer may be used. The positive electrode material mixture slurry thus obtained is applied onto one or both surfaces of the positive electrode current collector, dried, and then rolled into a predetermined thickness to yield a positive electrode active material layer, whereby the positive electrode 50 is obtained.

When the negative electrode 51 is the electrode of the present invention or when the positive electrode 50 is the electrode of the present invention, the electrode includes a negative electrode current collector (not shown) and a negative electrode active material layer (not shown).

As the negative electrode current collector, a commonly used one in this field may be used, examples of which include metallic foils and metallic films, made of copper, nickel, iron, an alloy containing at least one of these, and the like. Among these, metallic foils and metallic films, made of copper or a copper alloy, and the like are preferred. As the copper alloy, the copper alloys exemplified herein above may be used. In the case of a metallic foil made of copper or a copper alloy, examples of the foil include an electrolytic copper foil, an electrolytic copper alloy foil, a rolled copper foil, a copper alloy foil, a rolled copper alloy foil, a foil obtained by roughening the surface of these foils, and the like. Preferred foils for surface-roughening are an electrolytic copper foil, a rolled copper foil, a copper alloy foil, and the like.

The thickness of the negative electrode current collector is not particularly limited, but preferably 5 μm to 100 μm, and more preferably 8 to 35 μm. When the thickness of the negative electrode current collector is less than 5 μm, the mechanical strength of the negative electrode current collector may become insufficient, which will reduce the ease of handling thereof in the production of the electrode. In addition, the rupture of the electrode will easily occur during charging of the battery. On the other hand, when the thickness of the negative electrode current collector exceeds 100 μm, although the mechanical strength is ensured, the ratio of the volume the negative electrode current collector to that of the electrode is increased, and consequently the capacity of the battery may not be improved sufficiently.

The negative electrode active material layer is formed on one or both surfaces of the negative electrode current collector in its thickness direction and contains a negative electrode active material and, as needed, a conductive material, a binder, a thickener, and the like. Examples of the negative electrode active material include graphite materials such various natural graphites and artificial graphites; silicon-based composite materials such as silicide; alloy-based negative electrode active materials; and the like. Examples of the conductive material are the same as those added to the positive electrode active material layer. Examples of the binder are also the same as those added to the positive electrode active material layer, and in addition. In view of improving the lithium ion acceptability, examples of the binder further include styrene-butadiene copolymer rubber (SBR) particles and modified SBR, and the like.

As the thickener, a commonly used one in this field may be used. In particular, a thickener with water-solubility and being viscous in the form of an aqueous solution is preferred, examples of which include cellulose-based resins such as carboxymethylcellulose (CMC), and modified materials thereof; polyoxyethylene (PEO); and polyvinyl alcohol (PVA). Among these, cellulose-based resins and modified materials thereof are particularly preferred in view of the dispersability and the thickening property of a negative electrode material mixture slurry as described later.

The negative electrode 51 can be produced in the same manner as the positive electrode 50 except that the negative electrode material mixture slurry is prepared by mixing and dispersing a negative electrode active material, and, as needed, a conductive material, a binder, a thickener, and the like into a dispersion medium.

As the separator 52, a commonly used one in the field of non-aqueous electrolyte secondary batteries may be used. For example, a porous film made of polyolefin such as polyethylene and polypropylene is used alone or in combination, which is typical and preferred as an embodiment. More specifically, a porous film made of a synthetic resin may be used as the separator 52. Examples of the synthetic resin include polyolefin, such as polyethylene and polypropylene; aramid resins; polyamide-imides; polyphenylene sulfides; and polyimides. Examples of the porous film include microporous films, non-woven fabrics, and the like.

In addition, the separator 52 may include a heat-resistant filler, such as alumina, magnesia, silica, or titania, in its interior or on its surface. Alternatively, a heat-resistant layer may be provided on one or both surfaces of the separator 52 in its thickness direction. The heat-resistant layer includes, for example, the above-described heat-resistant filler and a binder. As the binder, the same binder as used in the positive electrode active material layer may be used. The thickness of the separator 52 is not particularly limited, but preferably 10 μm to 30 μm, and more preferably 10 to 25 μm.

As the non-aqueous electrolyte, a liquid electrolyte in which a solute is dissolved in an organic solvent; a polymer or solid electrolyte including a solute and an organic solvent immobilized with a polymer compound; and the like may be used. In the case of using a liquid electrolyte, it is preferable to impregnate the separator 52 with the liquid electrolyte. The non-aqueous electrolyte may include an additive in addition to the solute, the organic solvent, and the polymer compound.

The solute is selected based on the redox potential of the active material, and the like. Specifically, as the solute, a commonly used solute in the field of lithium batteries may be used, examples of which include LiPF₆, LiBF₄, LiClO₄, LiAlCl₄, LiSbF₆, LiSCN, LiCF₃SO₃, LiN(CF₃CO₂), LiN(CF₃SO₂)₂, LiAsF₆, LiB₁₀Cl₁₀, lithium lower aliphatic carboxylate, LiF, LiCl, LiBr, LiI, chloroborane lithium, borates such as lithium bis(1,2-benzenedioleate(2-)-O,O′) borate, lithium bis(2,3-naphtalenedioleate(2-)-O,O′) borate, lithium bis(2,2′-biphenyldioleate(2-)-O,O′) borate, and lithium bis(5-fluoro-2-oleate-1-benzenesulfonate-O,O′) borate, (CF₃SO₂)₂NLi, LiN(CF₃SO₂)(C₄F₉SO₂), (C₂F₅SO₂)₂NLi, lithium tetraphenylborate, and the like. These solutes may be used alone or, as needed, in combination of two or more.

As the organic solvent, a commonly used organic solvent in the field of lithium batteries may be used, examples of which include ethylene carbonate (EC), propylene carbonate (PC), butylene carbonate, vinylene carbonate, dimethyl carbonate (DMC), diethyl carbonate, ethyl methyl carbonate (EMC), dipropyl carbonate, methyl formate, methyl acetate, methyl propionate, ethyl propionate, dimethoxymethane, γ-butyrolactone, γ-valerolactone, 1,2-diethoxyethane, 1,2-dimethoxyethane, ethoxymethoxyethane, trimethoxymethane, tetrahydrofuran, tetrahydrofuran derivatives such as 2-methyltetrahydrofuran and the like, dimethylsulfoxide, 1,3-dioxolane, dioxolane derivatives such as 4-methyl-1,3-dioxolane and the like, formamide, acetamide, dimethylformamide, acetonitrile, propylnitrile, nitromethane, ethyl monoglyme, phosphoric acid triester, acetic acid ester, propionic acid ester, sulfolane, 3-methylsulfolane, 1,3-dimethyl-2-imidazolidinone, 3-methyl-2-oxazolidinone, propylene carbonate derivatives, ethyl ether, diethyl ether, 1,3-propanesultone, anisole, fluorobenzene, and the like. These organic solvents may be used alone or in combination of two or more.

As the additive, for example, an additive such as vinylene carbonate, cyclohexylbenzene, biphenyl, diphenyl ether, vinylethylene carbonate, divinylethylene carbonate, phenylethylene carbonate, diallyl carbonate, fluoroethylene carbonate, catechol carbonate, vinyl acetate, ethylene sulfite, propane sultone, trifluoropropylene carbonate, dibenzofuran, 2,4-difluoroanisole, o-terphenyl, and m-terphenyl may be included. These additives may be used alone or, as needed, in combination of two or more.

As for the non-aqueous electrolyte, a solid electrolyte prepared by adding the above-described solute into a mixture of one or two or more polymer materials such as polyethylene oxide, polypropylene oxide, polyphosphazene, polyaziridine, polyethylene sulfide, polyvinyl alcohol, polyvinylidene fluoride, and polyhexafluoropropylene may be used. Further, a gelled electrolyte prepared by mixing with the above-described organic solvent may be used. Furthermore, an inorganic material, such as a lithium nitride, a lithium halide, a lithium oxyacid salt, Li₄SiO₄, Li₄SiO₄—LiI—LiOH, Li₃PO₄—Li₄SiO₄, Li₂SiS₃, Li₃PO₄—Li₂S—SiS₂, and a phosphorus sulfide compound, may be used as a solid electrolyte. In the case of using a solid electrolyte or a gelled electrolyte, such an electrolyte may be disposed between the positive electrode 50 and the negative electrode 51 in place of the separator 52. Alternatively, the gelled electrolyte may be disposed adjacently to the separator 52.

As for the positive electrode lead 42, the negative electrode lead, the insulating plate 44, the sealing plate 45, the gasket 46, and the battery case 47, a commonly used one in the field of non-aqueous electrolyte secondary batteries may be used for each component. The sealing plate 45 is provided with a positive terminal 53 at its center.

The non-aqueous electrolyte secondary battery 40 of the present invention is produced, for example, in the following manner. One end of the positive electrode lead 42 and one end of the negative electrode lead are electrically connected to the positive electrode current collector of the positive electrode 50 and the negative electrode current collector of the negative electrode 51, respectively. The electrode plate group 41 is housed in the bottomed-cylindrical battery case 47 together with the sealing plate 44. The other end of the negative electrode lead extended from the lower portion of the electrode plate group 41 is connected to the bottom of the battery case 47, and the other end of the positive electrode lead 42 extended from the upper portion of the electrode plate group 41 is connected to the sealing plate 45. Subsequently, a predetermined amount of the non-aqueous electrolyte (not shown) is injected into the battery case 47. Thereafter, the sealing plate 45 with the gasket 46 disposed on its periphery is inserted into the opening of the battery case 47, and the opening of the battery case 47 is curled inward and crimped to seal the opening, whereby the non-aqueous electrolyte secondary battery 40 is obtained.

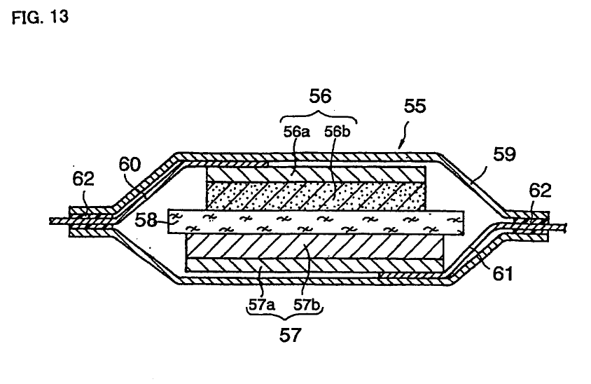

FIG. 13 is a cross-sectional view schematically showing a configuration of a laminated battery 55 as one embodiment of the present invention. The laminated battery 55 includes a positive electrode 56, a negative electrode 57, a separator 58, a battery case 59, a positive electrode lead 60, a negative electrode lead 61, and a sealing resin 62. The positive electrode 56 includes a positive electrode current collector 56a and a positive electrode active material layer 56b formed on one surface of the positive electrode current collector 56a in its thickness direction. The negative electrode 57 includes a negative electrode current collector 57a and a negative electrode active material layer 57b formed on one surface of the negative electrode current collector 57a in its thickness direction. The positive electrode 56 and the negative electrode 57 are disposed so as to be opposite to each other with the separator 58 interposed therebetween. In other words, in the laminated battery 55, the positive electrode 56, the separator 58, and the negative electrode 57 are laminated in this order and formed into a flat electrode plate group. The positive electrode 56, the negative electrode 57, and the separator 58 have the same configuration of the positive electrode 50, the negative electrode 51, and the separator 52 in the non-aqueous electrolyte secondary battery 40, respectively.

The battery case 59 is a container member with two openings and houses the electrode plate group in its internal space. Each of the two openings of the battery case 59 is sealed with the sealing resin 62. One end of the positive electrode lead 60 is electrically connected to the positive electrode current collector 56a, and the other end thereof is extended outside of the battery 55 from one opening of the battery case 59. One end of the negative electrode lead 61 is electrically connected to the negative electrode current collector 57a, and the other end thereof is extended outside of the battery 55 from the other opening of the battery case 59. The same non-aqueous electrolyte as used in the non-aqueous electrolyte secondary battery 40 can be used in the laminated battery 55.

As described above, the non-aqueous electrolyte secondary battery of the present invention can adopt various forms, examples of which include a prismatic battery having a spirally-wound electrode plate group, a cylindrical battery having a spirally-wound electrode plate group, a laminated battery having a laminated electrode plate group, and the like.

According to the production method of a current collector and an electrode plate for a non-aqueous secondary battery according to the present invention, it is possible to ensure the strength of the current collector for use in producing an electrode plate as well as to allow an electrode active material to be efficiently carried on the projections formed on the current collector, thereby to provide a highly reliable non-aqueous secondary battery which is useful as a power source for portable electronic equipment, the power source being increasingly expected to have an improved capacity as electronic equipment and communication equipment become more multi-functional.

### EXAMPLES

The present invention is described below in detail with reference to examples and comparative examples.

### Example 1

### Production of Negative Electrode Current Collector

The current collector 1 for negative electrode of the present invention was produced as follows using the current collector production apparatus 35 shown in FIG. 3. The roller 4 was a cemented carbide roller of 50 mm in diameter with the recesses 4a formed on its peripheral surface in the same arrangement pattern as shown in FIG. 5(a). The opening of the recesses 4a had a diameter of 10 μm and the recesses had a depth of 8 μm. The bulge formed on the rim of the opening of the recesses 4a as a result of formation of the recesses 4a by laser machining was removed by grinding. The roller 5 was an iron roller of 50 mm in diameter with a flat peripheral surface. The contact pressure between the rollers 4 and 5 at the press nip 6 was 10 kN in terms of the line pressure.

A copper foil for current collector having a thickness t₀ of 18 μm was wound around the metallic foil feeding roller 36 and mounted on the current collector production apparatus 35 shown in FIG. 3. The copper foil for current collector was passed through the press nip 6 of the processing means 37 and partially uncompressed, whereby the current collector 1 including the base 2 and the projections 3 as shown in FIG. 1(c) was formed, which was wound around the winding-up roller 38. Here, t₁ was 17 μm, and t₂ was 21 μm, that is, t₂>t₀>t₁.

Portions on a surface of the current collector 1 facing the recesses 4a on the peripheral surface of the roller 4 undergone plastic deformation that occurred in association with the compression on the other portions, and were finally formed into the projections 3. Another surface of the current collector 1 facing the roller 5 with a flat peripheral surface was flat without projections formed thereon.

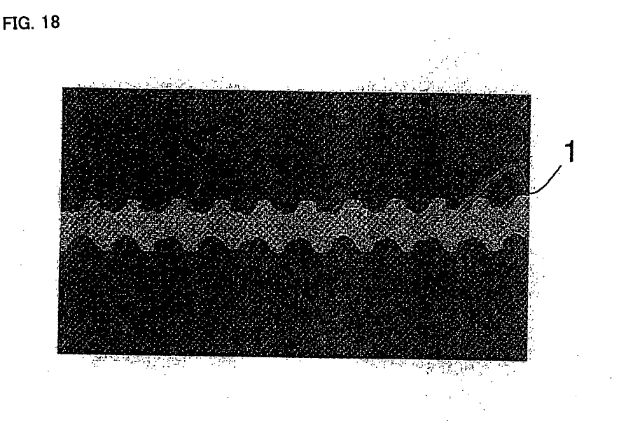

The cross section of the current collector 1 thus obtained in its thickness direction was observed under a scanning electron microscope. FIG. 18 is an electron micrograph of the cross section of the current collector 1. From FIG. 18, it is clear that the current collector 1 is free of defects such as crinkling, warping, and wrinkling.

### (Production of Negative Electrode)

The current collector 1 produced above was placed in the interior of a vacuum vapor deposition apparatus provided with an electron beam heating means. Vapor deposition was performed with the use of silicon having a purity of 99.9999% as a target while oxygen having a purity of 99.7% was introduced, whereby a 20-μm-thick SiO_{0.5} layer was formed on the projections 3 of the current collector 1. The current collector with the SiO_{0.5} layer was slit into a predetermined width to yield a negative electrode plate.

### Example 2

The current collector 1 for negative electrode was produced in the same manner as in Example 1 except that the roller 4 was used with the bulge unremoved by grinding, the bulge being formed during the formation of the recesses 4a of the roller. Here, t₁ was 17 μm, and t₂ was 21 μm, that is, t₂>t₀>t₁. The cross section of the current collector 1 thus obtained was observed in the same manner as in Example 1 under an electron microscope. As a result, no defects such as crinkling, warping, and wrinkling were observed. On the surfaces of the projections 3 of the current collector 1 for negative electrode, a 20-μm-thick SiO_{0.5} layer was formed in the same manner as in Example 1, which was then slit into a predetermined width to yield a negative electrode plate.

The current collectors 1 for negative electrode produced in Examples 1 and 2 had the projections 3 formed on one surface of the copper foil by the compression of the present invention. In such current collectors 1 for negative electrode, a negative electrode active material was efficiently vapor-deposited on the surfaces of the projections 3. The current collectors 1 for negative electrode further had a sufficient durability against tensile stress applied thereto in their longitudinal direction. As such, in the steps of vapor-depositing a negative electrode active material on the current collectors 1 for negative electrode, slitting into a predetermined width after vapor deposition of the negative electrode active material, and other steps, the occurrence of local deformation or deflection or the like on the current collectors 1 for negative electrode was prevented, and the separation of the negative electrode active material layer was inhibited.

### Example 3

The current collector 15 for negative electrode as shown FIG. 6(c) including the projections 17x and 17y formed on both surfaces of the base 16 in its thickness direction was produced in the same manner as in Example 1 except that the roller 4 was used in place of the roller 5 in the current collector production apparatus 35. Here, t₃ was 16 μm, and t₄ was 25 μm, that is, t₄>t₀>t₃. The cross section of the current collector 15 thus obtained was observed in the same manner as in Example 1 under an electron microscope. As a result, no defects such as crinkling, warping, and wrinkling were observed. On the surfaces of the projections 17x and 17y of the current collector 15 for negative electrode, a 20-μm-thick SiO_{0.5} layer was formed in the same manner as in Example 1, which was then slit into a predetermined width to yield a negative electrode plate.

### Example 4

The current collector 15 for negative electrode as shown FIG. 6(c) including the projections 17x and 17y formed on both surfaces of the base 16 in its thickness direction was produced in the same manner as in Example 2 except that the roller 4 was used in place of the roller 5 in the current collector production apparatus 35. Here, t₃ was 16 μm, and t₄ was 25 μm, that is, t₄>t₀>t₃. The cross section of the current collector 15 thus obtained was observed in the same manner as in Example 1 under an electron microscope. As a result, no defects such as crinkling, warping, and wrinkling were observed. On the surfaces of the projections 17x and 17y of the current collector 15 for negative electrode, a 20-μm-thick SiO_{0.5} layer was formed in the same manner as in Example 1, which was then slit into a predetermined width to yield a negative electrode plate.

The current collectors 15 for negative electrode produced in Examples 3 and 4 had the projections 17x and 17y formed on both surfaces of the copper foil due to partial plastic deformation that occurred in association with the compression of the present invention. As such, in such current collectors 15 for negative electrode, a negative electrode active material was efficiently vapor-deposited on the surfaces of the projections 17x and 17y. The current collectors 15 for negative electrode further had a sufficient durability against tensile stress applied thereto in their longitudinal direction. As such, in the steps of vapor-depositing a negative electrode active material on the current collectors 15 for negative electrode, slitting into a predetermined width after vapor deposition of the negative electrode active material, and other steps, the occurrence of local deformation or deflection or the like on the current collectors 15 for negative electrode was prevented, and the separation of the negative electrode active material layer was inhibited.

### Comparative Example 1

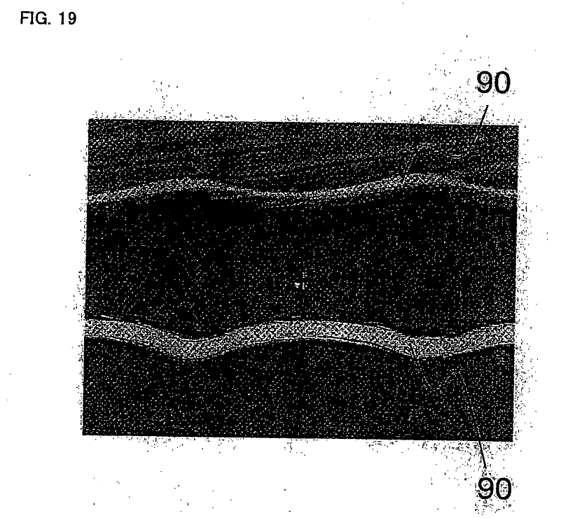

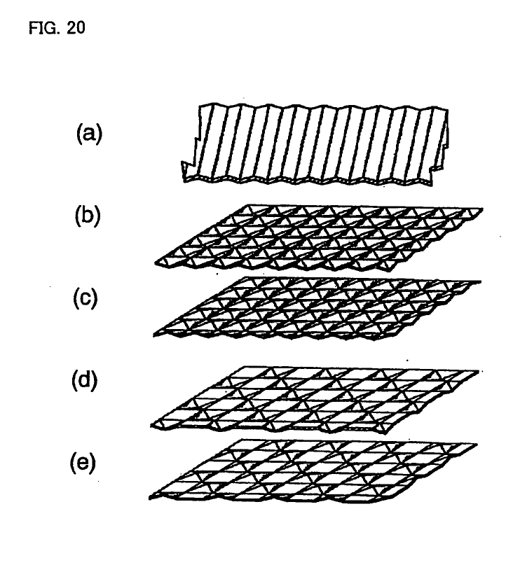

A 50-mm-diameter cemented carbide roller with a flat peripheral surface was machined such that the peripheral surface thereof had a shape as shown in FIG. 20(a). A 18-μm-thick copper foil for current collector was compressed in the same manner as in Example 1 except that this roller was used in place of the roller 4 in the current collector production apparatus 35. The cut cross section of the compressed copper foil was observed under a scanning electron microscope. FIG. 19 is an electron micrograph of the cross section of a current collector 90 obtained as Comparative Example 1. From FIG. 19, it is clear that crinkling occurred in the current collector of Comparative Example 1. For confirmation, the copper foil for current collector was compressed using a rubber roller in place of the roller 5 in the current collector production apparatus 35. As a result, crinkling still occurred.

It is clear from the foregoing results that the current collector obtained by the production method of the present invention has on its surface a plurality of projections formed by partial plastic deformation associated with the compression, and the projections have sufficient durability. As such, in the steps of forming projections on the surface of a metallic foil, allowing an electrode active material to be carried on the projections of the current collector, and other steps, the occurrence of local deformation or deflection or the like on the current collector can be prevented. Moreover, in the steps of allowing an electrode active material to be carried on the projections of the current collector, slitting into a predetermined width, and other steps, the separation of the electrode active material layer can be inhibited.

Further, in the current collector obtained by the production method of the present invention, the end surfaces of the projections of the current collector are little influenced by the compression and the plastic deformation and, therefore, have little or no distortion due to processing but have an excellent surface accuracy, enabling a uniform formation of a thin film thereon. Moreover, the surface roughness of the end surfaces of the projections is not damaged by the compression and maintains its initial surface roughness, enabling an improvement in adhesion with a thin film of active material layer. From this point of view, in order to further enhance the adhesion between the flat surfaces of the projections and the active material, it is considered effective to roughen the surface of the current collector before processing beforehand.

### Example 5

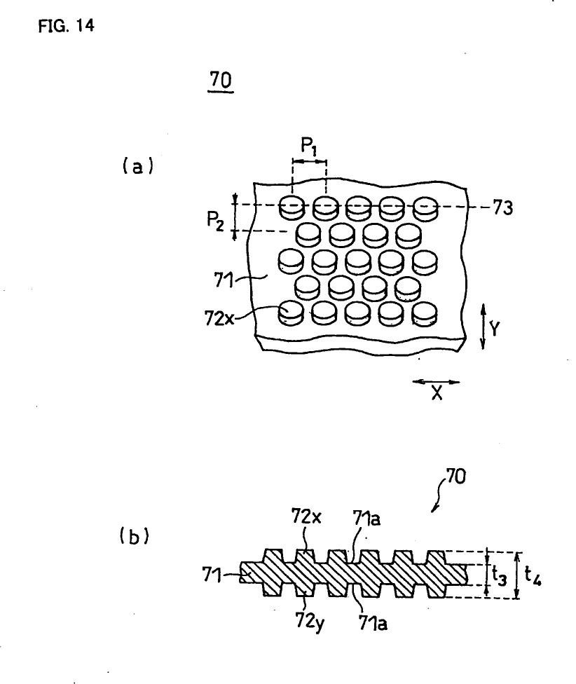

Ceramic rollers provided with a plurality of the recesses 4a each having a depth of 10 μm and an approximately circular opening with a diameter of 10 μm were mounted as the rollers 4 and 5 on the current collector production apparatus 35 shown in FIG. 3. A band of 15-μm-thick aluminum foil serving as the metallic foil 10 for current collector was passed through the press nip 6 in the current collector production apparatus 35 under a line pressure of 10 kN and partially uncompressed, whereby a current collector 70 for positive electrode as shown in FIG. 14 was formed. FIG. 14 is a set of drawings schematically showing a configuration of the current collector 70 being one embodiment of the present invention. FIG. 14(a) is a perspective view of the current collector 70. FIG. 14(b) is a longitudinal cross-sectional view of the current collector 70, namely, a cross-sectional view in its thickness direction.

The current collector 70 thus obtained was a band of current collector including a base 71 made of aluminum and approximately circular projections 72x and 72y of 4 μm in height (hereinafter referred to as “projections 72”) formed regularly on both surfaces of the base 71 in its thickness direction, the base having a thickness t₃ of 12 μm and a maximum thickness t₄ of 20 μm. In the widthwise direction (longitudinal direction) X, the projections 72 were aligned in a row at a pitch P₁, forming row units 73. In the latitudinal direction Y, the row units 73 were aligned in parallel at a pitch P₂. One row unit 73 and another row unit 73 adjacent thereto were arranged such that the projections 72 of one row unit were staggered from those of another row unit by a distance of 0.5P₁ in the widthwise direction X. The foregoing aligned pattern of the projections 72 was of a closest-packed array.

Next, the current collectors 70 including the projections 72 each having different volume ratios relative to the internal space volume of the recesses 4a were produced in the same manner as above except that an aluminum foil having a length of 1000 mm and a thickness of 15 μm was used and the contact pressure at the press nip 6 was adjusted so that the volume ratio of the projections 72 was changed as shown in Table 1. The surface condition of the current collectors 70 thus obtained was evaluated. In the evaluation, one thousand current collectors 70 were checked visually for wrinkling, warping, and tearing to count the number of current collectors having such defects and calculate the occurrence rate of each defect. The results are shown in Table 1.

Here, in Table 1, the volume ratio of projections is a percentage of the volume of the projections 72 to the internal space volume of the recesses 4a. This applies to the following description.

TABLE 1

| Volume ratio | Occurrence | Occurrence | Occurrence |
|---|---|---|---|
| of | rate of | rate of | rate of |
| projections | wrinkling | warping | tearing |
| (%) | (%) | (%) | (%) |
| 55 | 0 | 0 | 0 |
| 65 | 0 | 0 | 0 |
| 75 | 0 | 0 | 0 |
| 81 | 0 | 0 | 0 |
| 83 | 0 | 0 | 0 |
| 85 | 0 | 0 | 0 |
| 87 | 3 | 5 | 0.8 |
| 89 | 7 | 14 | 3 |

In producing the current collectors 70, tensile stress is applied to the current collectors 70 in the longitudinal direction X. If the current collectors 70 have no durability against tensile stress, defects such as wrinkling, warping, and tearing occur on the current collectors 70. As is evident from Table 1, when the volume ratio of the projections 72 was 85% or less, due to such volume ratios coupled with the closest-packed array of the approximately circular projections 72, the current collectors 70 had a sufficient durability against the tensile stress applied thereto in the longitudinal direction X, and the occurrence of the defects as described above was prevented. In this Example, examples in which the volume ratio of the projections 72 was less than 55% were not described. It should be noted, however, that when less than 55%, because of a lower contact pressure, the production of the current collectors 70 without the occurrence of defects as described above was possible.

In contrast, when the volume ratio of the projections 72 was more than 85%, the strength of a surface 71a of the base 71 was insufficient, and therefore defects such as wrinkling, warping, and tearing occurred locally.

The surface roughness of the current collectors 70 for positive electrode having a volume ratio of the projections 72 of 85% or less were measured with a surface roughness meter. As a result, the surface roughness of the surface 71a of the base 71 was smaller than that of the aluminum foil before processing. The surface roughness of the surface 71a of the base 71 was approximately equal to that of the peripheral surface of the ceramic roller.

The surface roughness of the end surfaces of the projections 72 was approximately equal to that of the aluminum foil before processing. The end surfaces of the projections 72 were observed under a scanning electron microscope. As a result, fine scratches similar to those as observed on the surface of the aluminum foil before processing were found.

The current collectors 70 were subjected to crystal orientation analysis by electron back scattering pattern (EBSP) method. As a result, the crystal grains in the surface 71a of the base 71 and the interior of the projections 72 were finer than those of the aluminum foil before processing. Further, the tensile strength of the current collectors 70 was measured. As a result, the thickness of the base 71 was reduced as compared with that of the aluminum foil before processing, but the tensile strength was not reduced. This was presumably because the base 71 was compressed and hardened by compression, resulting in an improvement in the tensile strength.

Based on the foregoing analysis results, it is considered that in the foregoing processing on an aluminum foil, compression was not applied to the projections 72 but was applied to the surface 71a of the base 71, and thus the current collectors 70 were obtained.

### Example 6

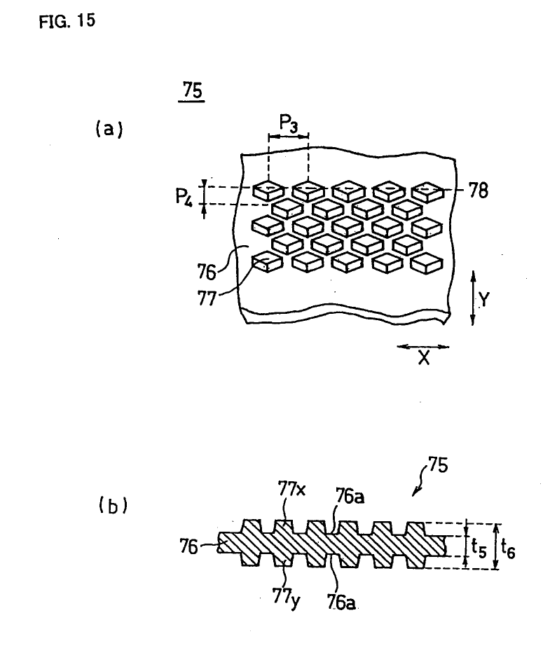

Ceramic rollers provided with a plurality of the recesses 4a each having a depth of 10 μm and an approximately rhombic opening with a diameter of 20 μm (long diagonal length of rhombus) were mounted as the rollers 4 and 5 on the current collector production apparatus 35 shown in FIG. 3. A band of 12-μm-thick copper foil serving as the metallic foil 10 for current collector was passed through the press nip 6 in the current collector production apparatus 35 under a line pressure of 10 kN and partially uncompressed, whereby a current collector 75 for positive electrode as shown in FIG. 15 was formed. FIG. 15 is a set of drawings schematically showing a configuration of the current collector 75 being one embodiment of the present invention. FIG. 15(a) is a perspective view of the current collector 75. FIG. 15(b) is a longitudinal cross-sectional view of the current collector 75.

The current collector 75 thus obtained was a band of current collector including a base 76 made of copper and approximately rhombic projections 77x and 77y of 4 μm in height (hereinafter referred to as “projections 77”) formed regularly on both surfaces of the base 76 in its thickness direction, the base having a thickness t₃ of 10 μm and a maximum thickness t₄ of 18 μm. In the widthwise direction (longitudinal direction) X, the projections 77 were aligned in a row at a pitch P₃, forming row units 78. In the latitudinal direction Y, the row units 78 were aligned in parallel at a pitch P₄. One row unit 78 and another row unit 78 adjacent thereto were arranged such that the projections 78 of one row unit were staggered from those of another row unit by a distance of 0.5P₃ in the widthwise direction X. The foregoing aligned pattern of the projections 77 was of a closest-packed array.

Next, the current collectors 75 including the projections 77 each having different volume ratios relative to the internal space volume of the recesses 4a were produced in the same manner as above except that an copper foil having a length of 1000 mm and a thickness of 12 μm was used and the contact pressure at the press nip 6 was adjusted so that the volume ratio of the projections 77 was changed as shown in Table 2. The surface condition of the current collectors 75 thus obtained was evaluated. In the evaluation, one thousand current collectors 75 were checked visually for wrinkling, warping, and tearing to count the number of current collectors having such defects and calculate the occurrence rate of each defect. The results are shown in Table 2.

Here, in Table 2, the volume ratio of projections is a percentage of the volume of the projections 77 to the internal space volume of the recesses 4a. This applies to the following description.

TABLE 2

| Volume ratio | Occurrence | Occurrence | Occurrence |
|---|---|---|---|
| of | rate of | rate of | rate of |
| projections | wrinkling | warping | tearing |
| (%) | (%) | (%) | (%) |
| 55 | 0 | 0 | 0 |
| 65 | 0 | 0 | 0 |
| 75 | 0 | 0 | 0 |
| 81 | 0 | 0 | 0 |
| 83 | 0 | 0 | 0 |
| 85 | 0 | 0 | 0 |
| 87 | 1.4 | 3 | 0.4 |
| 89 | 5 | 9 | 1.7 |

In producing the current collectors 75, tensile stress is applied to the current collectors 75 in the longitudinal direction X. If the current collector 75 has no durability against tensile stress, defects such as wrinkling, warping, and tearing occur on the current collectors 75. As is evident from Table 2, when the volume ratio of the projections 77 was 85% or less, due to such volume ratios coupled with the closest-packed array of the approximately rhombic projections 77, the current collectors 75 had a sufficient durability against the tensile stress applied thereto in the longitudinal direction X, and the occurrence of the defects as described above was prevented. In this Example, examples in which the volume ratio of the projections 77 was less than 55% were not described. It should be noted, however, that when less than 55%, because of a lower contact pressure, production of the current collectors 75 without the occurrence of defects as described above was possible.

In contrast, when the volume ratio of the projections 77 was more than 85%, the strength of a surface 76a of the base 76 was insufficient, and therefore defects such as wrinkling, warping, and tearing occurred locally.

The surface roughness of the current collectors 75 for positive electrode having a volume ratio of the projections 77 of 85% or less was measured with a surface roughness meter. As a result, the surface roughness of the surface 76a of the base 76 was smaller than that of the copper foil before processing. The surface roughness of the surface 76a of the base 76 was approximately equal to that of the peripheral surface of the ceramic roller.

The surface roughness of the end surfaces of the projections 77 was approximately equal to that of the copper foil before processing. The end surfaces of the projections 77 ware observed under a scanning electron microscope. As a result, fine scratches similar to those as observed on the surface of the copper foil before processing were found.

The current collectors 75 were subjected to crystal orientation analysis by electron back scattering pattern (EBSP) method. As a result, the crystal grains in the surface 76a of the base 76 and the interior of the projections 77 were finer than those of the copper foil before processing. Further, the tensile strength of the current collectors 75 was measured. As a result, the thickness of the base 76 was reduced as compared with that of the copper foil before processing, but the tensile strength was not reduced. This was presumably because the base 76 was compressed and hardened by compression, resulting in an improvement in the tensile strength.

Based on the foregoing analysis results, it is considered that in the foregoing processing on an copper foil, compression was not applied to the projections 77 but was applied to the surface 76a of the base 76, and thus the current collectors 75 were obtained.

### Example 7

A band of the current collector 75 was formed in the same manner as in Example 6 except that a 18-μm-thick copper foil was used in place of the 12-μm-thick copper foil and the contact pressure at the press nip 6 was adjusted so that the volume ratio of the projections 77 was 80%. The current collector 77 had a sufficient durability against tensile stress applied thereto in the longitudinal direction X since the approximately rhombic projections 77 were aligned in the pattern of a closest-packed array. Because of this, in processing the current collector 75, the occurrence of local deformation and deflection on the current collector 75 was prevented and the separation of the active material from the current collector 75 was suppressed. Here, the processing of the current collector 75 includes the steps of allowing an active material to be carried on the surface of the current collector 75, slitting the electrode obtained by allowing an active material to be carried on the surface of the current collector 75, and other relevant steps.

The current collector 75 obtained above was placed in the interior of a vacuum vapor deposition apparatus provided with an electron beam heating means. Vapor deposition was performed with the use of silicon having a purity of 99.9999% as a target while oxygen having a purity of 99.7% was introduced, whereby a 25-μm-thick SiO_{0.5} layer was formed in a columnar shape on the projections 77 of the current collector 75. The current collector with the SiO_{0.5} layer was slit into a predetermined width suitable for a cylindrical non-aqueous electrolyte secondary battery, to yield a negative electrode plate. It should be noted that in the current collector 75, since the approximately rhombic projections 77 were aligned in the pattern of a closest-packed array, a negative electrode active material was efficiently adhered to the surfaces of the projections 77 when vapor-deposited thereto in the latitudinal direction Y.

According to the production methods of Examples 5 to 7 of the present invention, by using ceramic rollers with a plurality of recesses formed on their peripheral surfaces, plastic deformation is allowed to partially proceed on the surface of a metallic foil for current collector, and thus projections are formed. In addition, by adjusting the volume of the projections to be equal to or less than the internal space volume of the recesses, the variations in shape, size, and like are reduced. As a result, a current collector with improved mechanical strength and durability can be provided. Moreover, by selecting the aligning pattern of the projections, the durability of the current collector is further improved. Consequently, in the steps of forming projections on the surface of a metallic foil for current collector, producing an electrode by allowing an active material to be carried on the surface of the current collector, and other steps, the occurrence of local deformation, deflection, and the like on the current collector can be remarkably prevented. Furthermore, in the steps of producing an electrode by allowing an active material to be carried on the surface of the current collector, slitting the electrode into a predetermined width, and other steps, the exfoliation of the active material from the current collector can be prevented.

Further, according to the production methods of the present invention, the projections on the current collector are formed by plastic deformation associated with the compression, and the end surfaces of the projections are little influenced by plastic deformation and, therefore, have little or no distortion due to processing. As such, the end surfaces of the projections have an excellent surface accuracy, enabling a uniform formation of a thin film of active material layer on the end surfaces. Moreover, since the end surfaces of the projections are not compressed, the surface roughness is not reduced and maintains the surface roughness of the metallic foil for current collector. Presumably, for this reason, the adhesion with the active material layer is further improved. From this point of view, in order to further enhance the adhesion between the flat surfaces of the projections and the electrode active material, it is considered effective to roughen the surface of the current collector before processing beforehand.

### Example 8

The roller 28 as shown in FIG. 9 was produced as follows. On the peripheral surface of a 50-mm-diameter cemented carbide roller for forming projections, recesses each having a depth of 10 μm and an approximately circular opening with a diameter of 10 μm were formed by laser machining using a YAG laser. The laser pulse frequency in the laser machining was 1 KHz.

The recesses thus formed had bulges such as burrs or swellings formed on the rims of their openings, resulted in a partially increased surface roughness of the roller. For this reason, grinding was performed with diamond particles of 8 μm in average particle size serving as grinding particles, in a grinder equipped with a grinding pad, while water was being supplied thereto. The grinding was performed until the average surface roughness of the peripheral surface of the roller reached 0.4a. In such a manner, the bulges were removed and the recesses 29 whose opening rims 29a were formed of a curved surface, whereby the roller 28 was obtained.

The roller 28 had a surface roughness approximately equal to that of the metallic foil being a raw material of the current collector. As such, in the current collector obtained after the process of compression, the end surfaces of projections will maintain the same surface roughness as that of the original metallic foil, and the surface of the base after undergoing compression by the roller 28 will have a surface roughness approximately equal to that of the surface of the roller 28. In other words, the current collector will have an approximately equal surface roughness over the entire surface thereof. The use of such a current collector can further improve the adhesion between the current collector and the active material layer.

If the roller is used without applying grinding when compressing a metallic foil, stress is intensively applied to the bulges of the opening rims of the recesses, from which cracks may start to grow on the surface of the roller. When this occurs, the life of the roller will be shortened.

### Example 9

The roller 28 was produced in the same manner as in Example 8 except that diamond particles having an average particle size of 30 μm were used in place of the diamond particles having an average particle size of 8 μm.

### Example 10

The roller 28 was produced in the same manner as in Example 8 except that diamond particles having an average particle size of 53 μm were used in place of the diamond particles having an average particle size of 8 μm.

### Example 11

The roller 28 was produced in the same manner as in Example 8 except that diamond particles having an average particle size of 74 μm were used in place of the diamond particles having an average particle size of 8 μm. In this example, it was impossible to reduce the average surface roughness of the roller 28 to be less than 0.8a.

The rollers 28 obtained in Examples 8 to 11 were checked for the presence of grinding particles (diamond particles) remaining on the peripheral surface of the rollers 28 and the average surface roughness of the peripheral surface of the rollers 28 after diamond grinding, and the presence of damage on the peripheral surface of the rollers 28 after use in the current collector production. The presence of remaining grinding particles and the presence of damage were checked by electron microscopic observation. The results are shown in Table 3.

TABLE 3

| | | After diamond grinding | | |
|---|---|---|---|---|
| | Average | | Average | |
| | particle | | surface | Presence of |
| | size of | Presence of | roughness of | damage on |
| | grinding | remaining | peripheral | peripheral |
| | particles | grinding | surface of | surface of |
| | (μm) | particles | roller | roller |
| Example 8 | 8 | Yes | 0.4a | No |
| Example 9 | 30 | No | 0.4a | No |
| Example 10 | 53 | No | 0.4a | No |
| Example 11 | 74 | No | 0.8a | Yes |

From Table 3, when the grinding was performed with the diamond particles having an average particle size of 8 μm, the bulges on the opening rims 29a of the recesses 29 were removed and the opening rims 29a were formed into a curved surface, but the diamond particles remained in the recesses 29. The remaining diamond particles in the recesses 29 failed to be completely removed even by ultrasonic cleaning. When the production of a current collector was performed with the diamond particles remaining in the recesses 29, there were cases where the formation of projections was insufficient.

When the diamond particles having an average particle size of 74 μm were used, the average surface roughness of the peripheral surface of the roller 28 was 0.8 a at most, and the presence of unremoved bulges was observed at some recesses. When the diamond particles having an average particle size of 30 μm and 53 μm were used, it was possible to provide the rollers 28 in which the opening rims 29a of the recesses 29 were formed into a curved surface, no diamond particles remained in the recesses 29, and the average surface roughness of the peripheral surface was 0.4a or less.

With respect to the rollers 28 of Examples 9 and 10, grinding was performed on the opening rims 29a on the recesses 29 with diamond particles of 5 μm in average particle size serving as grinding particles, in a grinder equipped with a grinding pad, while water was being supplied thereto, thereby to form the grooves 29x having a width of about 1 μm and a depth of about 1 μm. The diamond particles having an average particle size of 5 μm are the smallest diamond particles among commercially available ones, the particle size distribution of which is controllable.

Such grooves 29x allows the air that would otherwise remain in the interior of the recesses during the formation of projections to be smoothly discharged outside of the recesses. It is possible, therefore, to eliminate the possibility that the air remaining in the interior of the recesses would be compressed and, due to the pressure of the compressed air, the projections would fail to undergo smooth plastic deformation due to the pressure of the compressed air, resulting in the variation of the shape, height, and the like of the projections.

It should be noted that in the current collector, the height of projections from the surface of the base is determined by taking into consideration of the characteristics of an electrode to be finally produced as well as the life of the roller 28, and the like. In order to prolong the service life of the roller 28, it is desirable to reduce the contact pressure at the press nip. Accordingly, it is desirable to adjust the contact pressure such that projections having a necessary height can be formed with a smallest possible contact pressure.

Compression was performed on a 26-μm-thick copper foil having a length of the direction perpendicular to the transferring direction thereof of 80 mm using the roller 28 with the grooves 29y formed thereon under the conditions that the contact pressure at the press nip was 80 kN, to allow the copper foil to undergo partial plastic deformation. As a result, projections in which the height from the surface of the base was 5.1 μm on average were formed.

Further, compression was performed on the copper foil in the same manner as above except that the rollers 28 of Examples 9 and 10 with no grooves 29y formed thereon were used. As a result, projections in which the height from the surface of the base was 3.4 μm on average were formed. The use of a solid lubricant or a liquid lubricant for improving releasability, abrasion, and lubrication allowed for the formation of projections having an increased height and a uniform shape.

### Example 12

On the peripheral surface of a 25-μm-diameter ceramic roller for forming recesses, the recesses 29 were formed in the same manner as in Example 9, thereby to yield the roller 28. This roller 28 was mounted as the roller 4 on the current collector production apparatus 35 shown in FIG. 3, and the press nip 6 was formed. A 18-μm-thick copper foil having a width of the direction perpendicular to the transferring direction thereof of 80 mm and a length of 100 m was supplied into the press nip 6 and compressed under a pressure of 80 kN to allow the copper foil to undergo partial plastic deformation. The current collector 20 as shown in FIG. 8 was thus produced.

### Example 13

The current collector 20 was produced in the same manner as in Example 12 except that the roller diameter of the roller for forming recesses was changed to 50 mm.

### Example 14

The current collector 20 was produced in the same manner as in Example 12 except that the roller diameter of the roller for forming recesses was changed to 100 mm.

### Example 15

The current collector 20 was produced in the same manner as in Example 12 except that the roller diameter of the roller for forming recesses was changed to 150 mm.

With respect to the current collectors 20 obtained in Examples 12 to 15, the average height of the projections 22 and the difference between the maximum and the minimum in the projections 22 were determined by electron microscopic observation. Here, the average projection height is an average of one hundred projections 22. The roller 28 after use in the production of the current collector 20 was checked visually for the presence of damage on the recesses 29. Here, the height of the projection 20 is a distance between the surface 21a of the base 21 and the end surface of the projection 20 in the direction perpendicular to the surface 21a. The results are shown in Table 4.

TABLE 4

| | | | Difference in | |
|---|---|---|---|---|
| | | Average | projection height | Presence of |
| | Roller | projection | between maximum | damage on |
| | diameter | height | and minimum | recesses of |
| | (mm) | (μm) | (μm) | roller |
| Example 12 | 25 | 8.0 | 4.2 | Yes |
| Example 13 | 50 | 7.4 | 1.8 | Yes |
| Example 14 | 100 | 4.1 | 1.1 | No |
| Example 15 | 150 | 2.1 | 1.2 | No |

From Table 4, when the roller diameter was 25 mm, the average height of the projections 22 was 8 μm. However, a comparatively large distortion occurred on the roller 28 itself, there was a great variation in the height of the projections 22. Moreover, some irregularity in the rotation of the roller 28 was observed, for which reason the continuous processing was considered impossible.

When the roller diameter was 50 mm, the average height of the projections 22 was 7.4 μm. A slight distortion was observed on the roller 28, and the variation in the height of the projections 22 was within about ±1 μm. The recesses 29 of the roller 28 after use in the production of the current collector 20 were observed. As a result, numerous cracks were found. From these results, the roller diameter is considered to have a great influence on the life of the roller 28.

When the roller diameter was 100 mm, the average height of the projections 22 was 4.1 μm, and the variation in the height of the projections 22 was within ±1 μm. The recesses 29 of the roller 28 after use in the production of the current collector 20 were observed. As a result, no cracks were found. In addition, a 500 m of the current collector 20 and a 1000 m of the current collector 20 were produced and observed, and again, no cracks were found on the recesses 29.

When the roller diameter was 150 mm, the average height of the projections 22 was 2.1 μm, and the variation in the height of the projections 22 was within ±1 μm. The recesses 29 of the roller 28 after use in the production of the current collector 20 were observed. As a result, no cracks were found. In addition, a 1000 m of the current collector 20 was produced and observed, and again, no cracks were found on the recesses 29. In order to obtain the projections 22 having a sufficient height, the contact pressure should be considerably increased, and this requires increase in size of the production equipment.

From the results shown in Tables 3 and 4, it was confirmed that the roller 28 produced in Example 14 can be suitably used. In the production of the roller 28, the diamond particles having an average particle size of 30 μm were used in the step of grinding, the grooves 29x were formed on the opening rims 29a of the recesses 29, the average surface roughness of the peripheral surface of the roller was 0.4a, and the roller diameter was 100 mm.

In the current collectors 20 produced in Examples 11 to 14, the boundaries 22a between the base 21 and the projections 22 were each formed of a curved surface, and the cross section of the projections 22 shown in FIG. 7 each had a taper shape. Because of this, the processability in the process of compression and the releasability of the current collector 20 from the roller 28 were improved, and the exfoliation of the projections 22 from the current collector 20 because of tight fit thereof into the recesses 29 of the roller 28 was prevented.

If a positive electrode plate formed by allowing a positive electrode active material to be carried on the current collector 20 including a large number of projections 22 susceptible to exfoliation is used to form an electrode plate group, the current collector 20 will be the cause of wrinkling of the positive electrode plate during repeated charge and discharge, resulting in the exfoliation of the positive electrode active material. This is presumably attributable to the variation in mechanical strength of the current collector 20.

As described above, when a pair of rollers are used in processing, pressure can be applied to an extremely small contact area, that is, the contact pressure can be increased. It is possible, therefore, to reduce the size of the current collector production apparatus 35.

### Example 16

A roller 28A having the same configuration as the roller 28 shown in FIG. 9 except that the recesses 29 have an approximately rhombic opening was produced as follows. On the peripheral surface of a 50-mm-diameter cemented carbide roller for forming projections, recesses each having a depth of about 10 μm and an approximately rhombic opening with a long diagonal length of 20 μm were formed by laser machining using a YAG laser. The laser pulse frequency in the laser machining was 1 KHz.

The recesses thus formed had bulges such as burrs or swellings formed on the rim of their openings, resulted in a partially increased surface roughness of the roller. In particular, in the case where the recesses had a rhombic opening, the burrs or swellings were oriented in a certain direction, deteriorating the surface shape as a whole. For this reason, grinding was performed with diamond particles of 8 μm in average particle size serving as grinding particles, in a grinder equipped with a grinding pad, while water was being supplied thereto. The grinding was performed until the average surface roughness of the peripheral surface of the roller reached 0.4a. By doing this, the bulges were removed and the recesses 29 whose opening rims 29a were formed of a curved surface were formed, whereby the roller 28A was obtained.

The roller 28A had a surface roughness approximately equal to that of the metallic foil being a raw material of the current collector. As such, in the current collector obtained after the process of compression, the end surfaces of projections will maintain the same surface roughness as that of the original metallic foil, and the surface of the base after undergoing compression by the roller 28A will have a surface roughness approximately equal to that of the surface of the roller 28A. In other words, the current collector will have an approximately equal surface roughness over the entire surface thereof. The use of such a current collector can further improve the adhesion between the current collector and the active material layer.

If the roller is used without applying grinding when performing compression on a metallic foil according to the present invention, stress is intensively applied to the bulges of the opening rims of the recesses, from which cracks may start to grow on the surface of the roller. When this occurs, the life of the roller will be shortened. In particular, in the case of an approximately rhombic opening, stress tends to be intensively applied to two acute corners thereof because of their shape, from which cracks may start to grow on the peripheral surface of the roller 28A, and spread and join with other cracks on the adjacent recesses 29. When this occurs, the life of the roller will be shortened.

### Example 17

The roller 28A was produced in the same manner as in Example 16 except that diamond particles having an average particle size of 30 μm were used in place of the diamond particles having an average particle size of 8 μm.

### Example 18

The roller 28A was produced in the same manner as in Example 16 except that diamond particles having an average particle size of 53 μm were used in place of the diamond particles having an average particle size of 8 μm.

### Example 19

The roller 28A was produced in the same manner as in Example 16 except that diamond particles having an average particle size of 74 μm were used in place of the diamond particles having an average particle size of 8 μm. In this example, it was impossible to reduce the average surface roughness to less than 0.8a.

The rollers 28A obtained in Examples 16 to 19 were checked for the presence of grinding particles (diamond particles) remaining on the peripheral surface of the rollers 28A and the average surface roughness of the peripheral surface of the rollers 28A after diamond grinding, and the presence of damage on the peripheral surface of the rollers 28A after use in the current collector production. The presence of remaining grinding particles and the presence of damage were checked by electron microscopic observation. The results are shown in Table 5.

TABLE 5

| | | After grinding | | |
|---|---|---|---|---|
| | Average | | Average | |
| | particle | | surface | Presence of |
| | size of | Presence of | roughness of | damage on |
| | grinding | remaining | peripheral | peripheral |
| | particles | grinding | surface of | surface of |
| | (μm) | particles | roller | roller |
| Example 16 | 8 | Yes | 0.4a | No |
| Example 17 | 30 | No | 0.4a | No |
| Example 18 | 53 | No | 0.4a | No |
| Example 19 | 74 | No | 0.8a | Yes |

From Table 5, when the grinding was performed with the diamond particles having an average particle size of 8 μm, the bulges on the opening rims 29a of the recesses 29 were removed and the opening rims 29a were formed into a curved surface, but the diamond particles remained in the recesses 29. The remaining diamond particles in the recesses 29 failed to be completely removed even by ultrasonic cleaning. When the production of a current collector was performed while the diamond particles remained in the recesses 29, there were cases where the formation of projections was insufficient.

When the diamond particles having an average particle size of 74 μm were used, the average surface roughness of the peripheral surface of the roller 28 was 0.8 a at most, and the presence of unremoved bulges was observed at some recesses. When the diamond particles having an average particle size of 30 μm and 53 μm were used, it was possible to provide the rollers 28 in which the opening rims 29a of the recesses 29 were formed into a curved surface, no diamond particles remained in the recesses 29, and the average surface roughness of the peripheral surface was 0.4a or less.

With respect to the rollers 28A of Examples 17 and 18, grinding was performed on the opening rims 29a on the recesses 29 with diamond particles of 5 μm in average particle size serving as grinding particles, in a grinder equipped with a grinding pad, while water was being supplied thereto, thereby to form the grooves 29x having a width of about 1 μm and a depth of about 1 μm. The diamond particles having an average particle size of 5 μm are the smallest diamond particles among commercially available ones, the particle size distribution of which is controllable.

Such grooves 29x allows the air that would otherwise remain in the interior of the recesses during the formation of projections to be smoothly discharged outside of the recesses. It is possible, therefore, to eliminate the possibility that the air remaining in the interior of the recesses would be compressed and, due to the pressure of the compressed air, the projections would fail to undergo smooth plastic deformation, resulting in the variation of the shape, height, and the like of the projections.

It should be noted that in the current collector, the height of projections from the base is determined by taking into consideration of the characteristics of an electrode to be finally produced as well as the life of the roller 28A, and the like. In order to prolong the service life of the roller 28A, it is desirable to reduce the contact pressure at the press nip. Accordingly, it is desirable to adjust the contact pressure such that projections having a necessary height can be formed with a smallest possible contact pressure. In particular, in the case of an approximately rhombic opening, in order to obtain a sufficient height, the contact pressure should be higher than that in the case of an approximately circular opening. Further, when compression is performed under the same conditions with a roller provided with recesses each having an approximately rhombic opening of the same plane-projected area as that of the approximately circular opening, the height is reduced by about 15% to 23%. This is presumably because the plastic deformation from the longitudinal axis cross section of the rhombic opening is influenced by the resistance due to the narrow cross-sectional shape of the corners.

Compression was performed on a 18-μm-thick copper foil having a length of the direction perpendicular to the transferring direction thereof of 80 mm using the roller 28A with the grooves 29y formed thereon under the conditions that the contact pressure at the press nip was 80 kN, to allow the copper foil to undergo partial plastic deformation. As a result, projections in which the height from the surface of the base was 7.1 μm on average were formed.

Further, compression was performed on the copper foil in the same manner as above except that the rollers 28A with no grooves 29y formed thereon were used. As a result, projections in which the height from the surface of the base was 5.5 μm on average were formed. The use of a solid lubricant or a liquid lubricant for improving releasability, abrasion, and lubrication allowed for the formation of projections having an increased height and a uniform shape.

### Example 20

The roller 28A was produced in the same manner as in Example 17 except that the recesses 29 were formed on a 25-mm-diameter ceramic roller for forming projections. The roller 28A thus produced was mounted as the rollers 4 and 5 on the current collector production apparatus 35 shown in FIG. 3, and the press nip 6 was formed. A 26-μm-thick copper foil having a width of the direction perpendicular to the transferring direction thereof of 80 mm and a length of 100 m was supplied into the press nip 6 and compressed under a pressure of 80 kN to allow the copper foil to undergo partial plastic deformation. The current collector 23 as shown in FIG. 10 was thus produced.

### Example 21

The current collector 23 was produced in the same manner as in Example 20 except that the roller diameter of the roller for forming recesses was changed to 50 mm.

### Example 22

The current collector 23 was produced in the same manner as in Example 20 except that the roller diameter of the roller for forming recesses was changed to 100 mm.

### Example 23

The current collector 23 was produced in the same manner as in Example 20 except that the roller diameter of the roller for forming recesses was changed to 150 mm.

With respect to the current collectors 23 obtained in Examples 20 to 23, the average height of the projections 25x and 25y (hereinafter referred to as “projections 25”) and the difference between the maximum and the minimum in the projections 25 were determined by electron microscopic observation. Here, the average projection height is an average of one hundred projections 25. The roller 28A after use in the production of the current collector 23 was checked visually for the presence of damage on the recesses 29. Here, the height of the projection 25 is a distance between the surface 24a of the base 24 and the end surface of the projection 25 in the direction perpendicular to the surface 24a of the base 24 in the cross section shown in FIG. 8. The results are shown in Table 6.

TABLE 6

| | | | Difference in | |
|---|---|---|---|---|
| | | Average | projection height | Presence of |
| | Roller | projection | between maximum | damage on |
| | diameter | height | and minimum | recesses of |
| | (mm) | (μm) | (μm) | roller |
| Example 20 | 25 | 10.0 | 5.6 | Yes |
| Example 21 | 50 | 8.2 | 2.1 | Yes |
| Example 22 | 100 | 7.1 | 1.7 | No |
| Example 23 | 150 | 4.3 | 1.6 | No |

From Table 6, when the roller diameter was 25 mm, the average height of the projections 25 was 10 μm. However, a comparatively large distortion occurred on the roller 28A itself, there was a great variation in the height of the projections 25. Moreover, some irregularity in the rotation of the roller 28A was observed, for which reason the continuous processing was considered impossible.

When the roller diameter was 50 mm, the average height of the projections 25 was 8.2 μm. A slight distortion was observed on the roller 28A, and the variation in the height of the projections 25 was within about ±1 m. The recesses 29 of the roller 28A after use in the production of the current collector 23 were observed. As a result, numerous cracks were found. From these results, the roller diameter is considered to have a great influence on the life of the roller 28A.

When the roller diameter was 100 mm, the average height of the projections 25 was 7.1 μm, and the variation in the height of the projections 25 was within ±1 μm. The recesses 29 of the roller 28A after use in the production of the current collector 23 were observed. As a result, no cracks were found. In addition, a 500 m of the current collector 23 and a 1000 m of the current collector 23 were produced and observed again, no cracks were found on the recesses 29.

When the roller diameter was 150 mm, the average height of the projections 25 was 4.3 μm, and the variation in the height of the projections 25 was within ±1 μm. The recesses 29 of the roller 28A after use in the production of the current collector 23 were observed. As a result, no cracks were found. In addition, a 1000 m of the current collector 23 was produced and observed again, no cracks were found on the recesses 29. In order to obtain the projections 25 having a sufficient height, the contact pressure should be considerably increased, and this requires increase in size of the production equipment.

From the results shown in Tables 5 and 6, it was confirmed that the roller 28A produced in Example 22 can be suitably used. In the production of the roller 28A, the diamond particles having an average particle size of 30 μm were used in the step of grinding, the grooves 29x were formed on the opening rims 29a of the recesses 29, the average surface roughness of the peripheral surface of the roller was 0.4a, and the roller diameter was 100 mm.

In the current collectors 23 produced in Examples 20 to 23, the boundaries 25a between the base 24 and the projections 25 were each formed of a curved surface, and the cross section of the projections 25 shown in FIG. 10 each had a taper shape. Because of this, the processability in the process of compression and the releasability of the current collector 23 from the roller 28A were improved, and the exfoliation of the projections 25 from the current collector 23 because of tight fit thereof into the recesses 29 of the roller 28A was prevented.

If a negative electrode plate formed by allowing a negative electrode active material to be carried on the current collector 23 including a large number of projections 25 susceptible to exfoliation is used to form an electrode plate group, the current collector 23 will be the cause of wrinkling of the negative electrode plate during repeated charge and discharge, resulting in the exfoliation of the negative electrode active material. This is presumably attributable to the variation in mechanical strength of the current collector 23.

As described above, when a pair of rollers are used in processing, pressure can be applied to an extremely small contact area, that is, the contact pressure can be increased. It is possible, therefore, to reduce the size of the current collector production apparatus 35.

### Example 24

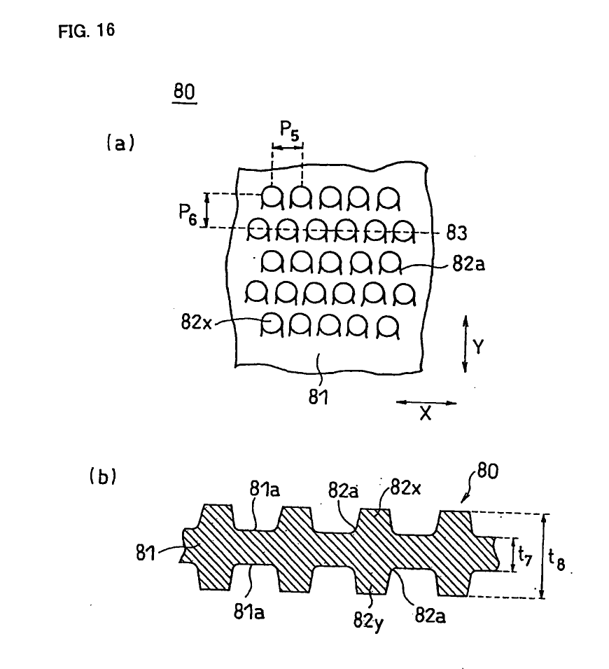

Ceramic rollers 28 as shown in FIG. 9 provided with a plurality of the recesses 29 each having a depth of 8 μm and an approximately circular opening with a diameter of 10 μm were mounted as the rollers 4 and 5 on the current collector production apparatus 35 shown in FIG. 3. A band of 15-μm-thick aluminum foil serving as the metallic foil 10 for current collector was passed through the press nip 34a (FIG. 11) in the current collector production apparatus 35 under a line pressure of 10 kN and partially uncompressed, whereby a current collector 80 for positive electrode as shown in FIG. 16 was formed. FIG. 16 is a set of drawings schematically showing a configuration of the current collector 80 being one embodiment of the present invention. FIG. 16(a) is a perspective view of the current collector 80. FIG. 16(b) is a longitudinal cross-sectional view of the current collector 80.

The current collector 80 thus obtained was a band of current collector including a base 81 made of aluminum and approximately circular projections 82x and 82y of 5 μm in height (hereinafter referred to as “projections 82”) formed regularly on both surfaces of the base 81 in its thickness direction, the base having a thickness t₇ of 12 μm and a maximum thickness t₈ of 20 μm. In the widthwise direction (longitudinal direction) X, the projections 82 were aligned in a row at a pitch P₅, forming row units 83. In the latitudinal direction Y, the row units 83 were aligned in parallel at a pitch P₆. One row unit 83 and another row unit 83 adjacent thereto were arranged such that the projections 82 of one row unit were staggered from those of another row unit by a distance of 0.5P₅ in the widthwise direction X. The foregoing aligned pattern of the projections 82 was of a closest-packed array.

In the current collector 80, the boundaries 82a between the base 81 and the projections 82 were each formed of a curved surface. This improves the processability and the releasability of the current collector 80 from the rollers 28 in the process of compression. In addition, due to the closest-packed array of the approximately circular projections 82, the current collector 80 had a sufficient durability against the tensile stress applied thereto in the longitudinal direction X. As such, in producing the current collector 80, processing the current collector 80, and the like, the occurrence of local deformation and deflection on the current collector 80 was prevented.

The surface roughness of the current collector 80 was measured with a surface roughness meter. As a result, the surface roughness of the surface 81a of the base 81 was smaller than that of the aluminum foil before processing. The surface roughness of the surface 81a of the base 81 was approximately equal to that of the ceramic rollers 28.

The surface roughness of the end surfaces of the projections 82 was approximately equal to that of the aluminum foil before processing. The surface roughness of the end surfaces of the projections 82 was observed under a scanning electron microscope. As a result, fine scratches similar to those as observed on the surface of the aluminum foil before processing were found.

The current collector 80 was subjected to crystal orientation analysis by electron back scattering pattern (EBSP) method. As a result, the crystal grains in the surface 81a of the base 81 and the interior of the projections 82 were finer than those of the aluminum foil before processing. Further, the tensile strength of the current collector 80 was measured. As a result, the thickness of the base 81 was reduced as compared with that of the aluminum foil before processing, but the tensile strength was not reduced. This was presumably because the hardness was increased by compression, resulting in an improvement in the tensile strength.

Based on the foregoing analysis results, it is considered that in the foregoing processing on an aluminum foil, compression was not applied to the projections 82 but was applied to the surface 81a of the base 81, and thus the current collector 80 was obtained.

A positive electrode material mixture slurry was applied onto both surfaces of the current collector 80 thus obtained, dried, and compressed such that the total thickness reached 126 μm, thereby to yield a positive electrode including two positive electrode active material layers each having a thickness of 58 μm. The positive electrode thus obtained was slit into a predetermined width to yield a positive electrode plate.

The positive electrode material mixture slurry was prepared by stirring, in an double arm kneader, 100 parts by weight of lithium cobalt oxide in which cobalt was partially replaced with nickel and manganese, 2 parts by weight of acetylene black serving as a conductive agent, 2 parts by weight of polyvinylidene fluoride serving as a binder, and an appropriate amount of N-methyl-2-pyrrolidone.

In the current collector 80, as shown in FIG. 16, the approximately circular projections 82 were aligned in the pattern of a closest-packed array and the boundaries 82a between the base 81 and the projections 82 were each formed of a curved surface. As such, the current collector 80 had a sufficient durability against tensile stress applied thereto in the longitudinal direction X. Because of this, in the step of producing a positive electrode by applying a positive electrode material mixture slurry onto the current collector 80, followed by drying and compressing, the step of slitting the positive electrode into a predetermined width, and other steps, the occurrence of local deformation and deflection on the current collector 80 was prevented and the exfoliation of the positive electrode active material layer was suppressed.

### Example 25

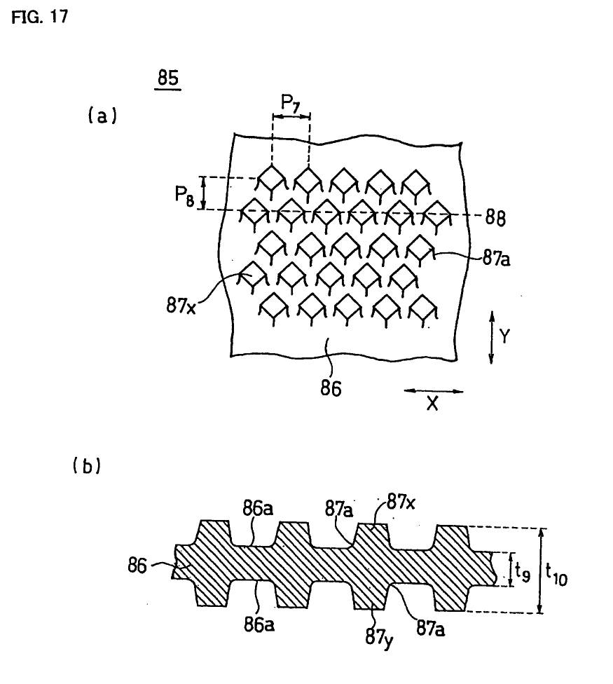

The ceramic rollers 28 as shown in FIG. 9 provided with a plurality of the recesses 29 each having a depth of 10 μm and an approximately rhombic opening with a long diagonal length of 20 μm were mounted as the rollers 4 and 5 on the current collector production apparatus 35 shown in FIG. 3. A band of 12-μm-thick copper foil serving as the metallic foil for current collector was passed through the press nip 34a (FIG. 11) in the current collector production apparatus 35 under a line pressure of 10 kN for performing compression, to allow the copper foil to undergo partial plastic deformation, whereby a current collector 85 for negative electrode as shown in FIG. 17 was formed. FIG. 17 is a set of drawings schematically showing a configuration of the current collector being one embodiment of the present invention. FIG. 17(a) is a perspective view of the current collector 85. FIG. 17(b) is a longitudinal cross-sectional view of the current collector 85.

The current collector 85 thus obtained was a band of current collector including a base 86 made of copper and approximately rhombic projections 87x and 87y of 6 μm in height (hereinafter referred to as “projections 87”) formed regularly on both surfaces of the base 86 in its thickness direction, the base having a thickness t₉ of 6 μm and a maximum thickness t₁₀ of 18 μm. In the widthwise direction (longitudinal direction) X, the projections 87 were aligned in a row at a pitch P₇, forming row units 88. In the latitudinal direction Y, the row units 88 were aligned in parallel at a pitch P₈. One row unit 88 and another row unit 88 adjacent thereto were arranged such that the projections 87 of one row unit were staggered from those of another row unit by a distance of 0.5P₇ in the widthwise direction X. The foregoing aligned pattern of the projections 87 was of a closest-packed array.

In the current collector 85, the boundaries 86a between the base 86 and the projections 87 were each formed of a curved surface. This improves the processability and the releasability of the current collector 85 from the rollers 28 in the process of compression. In addition, due to the closest-packed array of the approximately rhombic projections 87, the current collector 85 had a sufficient durability against the tensile stress applied thereto in the longitudinal direction X. As such, in producing the current collector 85, processing the current collector 85, and the like, the occurrence of local deformation and deflection on the current collector 85 was prevented.

The surface roughness of the current collector 85 was measured with a surface roughness meter. As a result, the surface roughness of the surface 86a of the base 86 was smaller than that of the copper foil before processing. The surface roughness of the surface 86a of the base 86 was approximately equal to that of the ceramic rollers 28.

The surface roughness of the end surfaces of the projections 87 was approximately equal to that of the copper foil before processing. The surface roughness of the end surfaces of the projections 87 was observed under a scanning electron microscope. As a result, fine scratches similar to those as observed on the surface of the copper foil before processing were found.

The current collector 85 was subjected to crystal orientation analysis by electron back scattering pattern (EBSP) method. As a result, the crystal grains in the surface 86a of the base 86 and the interior of the projections 87 were finer than those of the copper foil before processing. Further, the tensile strength of the current collector 85 was measured. As a result, the thickness of the base 86 was reduced as compared with that of the copper foil before processing, but the tensile strength was not reduced. This was presumably because the hardness was increased by compression, resulting in an improvement in the tensile strength.

Based on the foregoing analysis results, it is considered that in the foregoing processing on a copper foil, plastic deformation associated with compression occurred around the projections 87, compression was applied to the surface 86a of the base 86, and thus the current collector 85 was obtained.

The current collector 85 produced above was placed in the interior of a vacuum vapor deposition apparatus provided with an electron beam heating means. Vapor deposition was performed with the use of silicon having a purity of 99.9999% as a target while oxygen having a purity of 99.7% was introduced, whereby a 20-μm-thick SiO_{0.5} layer was formed in a columnar shape on the projections 87 on both surfaces of the current collector 85. The current collector with the SiO_{0.5} layer was slit into a predetermined width to yield a negative electrode plate.

In the current collector 85, as shown in FIG. 17(a), the approximately rhombic projections 87 were formed on both surfaces on the current collector 85 in the pattern of a closest-packed array and the boundaries 87a between the base 86 and the projections 87 were each formed of a curved surface. Because of this, in the step of vapor depositing a negative electrode active material along the longitudinal direction X of the current collector 85, the active material can be efficiently adhered to the surfaces of the projections 87.

Moreover, the current collector 85 had a sufficient durability against tensile stress applied thereto in the longitudinal direction X. Because of this, in the step of producing a band of current collector 85, the step of producing a negative electrode plate by vapor-depositing a negative electrode active material on the surface of the current collector 85, the step of slitting the negative electrode plate into a predetermined width, and other steps, the occurrence of local deformation and deflection on the current collector 85 was prevented and at the same time the separation of the negative electrode active material was suppressed.

### Example 26

The ceramic rollers 28 as shown in FIG. 9 provided with a plurality of the recesses 29 each having a depth of 10 μm and an approximately circular opening with a diameter of 10 μm were mounted as the rollers 4 and 5 on the current collector production apparatus 35 shown in FIG. 3. A band of 18-μm-thick copper foil serving as the metallic foil 10 for current collector was passed through the press nip 34a (FIG. 11) in the current collector production apparatus 35 under a line pressure of 10 kN for performing compression, to allow the copper foil to undergo partial plastic deformation, whereby the current collector 80 for negative electrode as shown in FIG. 16 was formed.

The current collector 80 thus obtained was a band of current collector including the base 81 made of copper and approximately circular projections 82x and 82y of 8 μm in height (hereinafter referred to as “projections 82”) formed regularly on both surfaces of the base 81 in its thickness direction, the base having a thickness t₇ of 10 μm and a maximum thickness t₈ of 26 μm. In the widthwise direction (longitudinal direction) X, the projections 82 were aligned in a row at a pitch P₅, forming row units 83. In the latitudinal direction Y, the row units 83 were aligned in parallel at a pitch P₆. One row unit 83 and another row unit 83 adjacent thereto were arranged such that the projections 82 of one row unit were staggered from those of another row unit by a distance of 0.5P₅ in the widthwise direction X. The foregoing aligned pattern of the projections 82 was of a closest-packed array.

In the current collector 80, the boundaries 82a between the base 81 and the projections 82 were each formed of a curved surface. This improves the processability and the releasability of the current collector 80 from the rollers 28 in the process of compression. In addition, due to the closest-packed array of the approximately circular projections 82, the current collector 80 has a sufficient durability against the tensile stress applied thereto in the longitudinal direction X. As such, in producing the current collector 80, processing the current collector 80, and the like, the occurrence of local deformation and deflection on the current collector 80 was prevented.

The surface roughness of the current collector 80 was measured with a surface roughness meter. As a result, the surface roughness of the surface 81a of the base 81 was smaller than that of the copper foil before processing. The surface roughness of the surface 81a of the base 81 was approximately equal to that of the ceramic rollers 28.

The surface roughness of the end surfaces of the projections 82 was approximately equal to that of the copper foil before processing. The surface roughness of the end surfaces of the projections 82 was observed under a scanning electron microscope. As a result, fine scratches similar to those as observed on the surface of the copper foil before processing were found.

The current collector 80 was subjected to crystal orientation analysis by electron back scattering pattern (EBSP) method. As a result, the crystal grains in the surface 81a of the base 81 and the interior of the projections 82 were finer than those of the copper foil before processing.

Further, the tensile strength of the current collector 80 was measured. As a result, the thickness of the base 81 was reduced as compared with that of the copper foil before processing, but the tensile strength was not reduced. This is presumably because the hardness was increased by compression, resulting in an improvement in the tensile strength.

Based on the foregoing analysis results, it is considered that in the foregoing processing on a copper foil, plastic deformation associated with compression occurred around the projections 82, compression was applied to the surface 81a of the base 81, and thus the current collector 80 was obtained.

The current collector 80 produced above was placed in the interior of a vacuum vapor deposition apparatus provided with an electron beam heating means. Vapor deposition was performed with the use of silicon having a purity of 99.9999% as a target while oxygen having a purity of 99.7% was introduced, whereby a 25-μm-thick SiO_{0.5} layer was formed in a columnar shape on the projections 82 on both surfaces of the current collector 80. The current collector with the SiO_{0.5} layer was slit into a predetermined width to yield a negative electrode plate.

In the current collector 80, as shown in FIG. 16(a), the approximately circular projections 82 were formed on both surfaces on the current collector 80 in the pattern of a closest-packed array and the boundaries 82a between the base 81 and the projections 82 were each formed of a curved surface. Because of this, in the step of vapor depositing a negative electrode active material along the longitudinal direction X of the current collector 80, the active material can be efficiently adhered to the surfaces of the projections 82.

Moreover, the current collector 80 had a sufficient durability against tensile stress applied thereto in the longitudinal direction X. Because of this, in the step of producing a band of current collector 80, the step of producing a negative electrode plate by vapor-depositing a negative electrode active material on the surface of the current collector 80, the step of slitting the negative electrode plate into a predetermined width, and other steps, the occurrence of local deformation and deflection on the current collector 80 was prevented and at the same time the separation of the negative electrode active material was suppressed.

With the use of the positive electrode plate obtained in Example 24 and the negative electrode plate obtained in the above, the cylindrical non-aqueous electrolyte secondary battery 40 as shown in FIG. 12 was fabricated. First, the positive electrode plate 50, the separator 52, the negative electrode plate 51, and the separator 52 were laminated in this order and wound spirally, to form the electrode plate group 41. This electrode plate group 41 was housed in the bottomed-cylindrical battery case 47 together with the sealing plate 44. One end of a negative electrode lead (not shown) extended from the lower portion of the electrode plate group 41 was connected to the bottom of the battery case 47, and one end of the positive electrode lead 42 extended from the upper portion of the electrode plate group 41 was connected to the sealing plate 45. Subsequently, a predetermined amount of a non-aqueous electrolyte (not shown) was injected into the battery case 47. Thereafter, the sealing plate 45 with the sealing gasket 46 disposed on its periphery was inserted into the opening of the battery case 47, and the rim of the opening of the battery case 47 was curled inward and crimped to seal the opening, whereby the non-aqueous secondary battery 40 of the present invention was fabricated.

After the spirally-wound electrode plate group 41 was produced in the foregoing non-aqueous secondary battery 40, this electrode plate group 41 was disassembled and observed. As a result, no defects such as tearing of electrode plate and separation of active material layer were observed in both the positive electrode plate 50 and the negative electrode plate 51. Further, this non-aqueous secondary battery 40 was subjected to 300 charge/discharge cycles. As a result, no cycle deterioration was observed. Furthermore, the non-aqueous secondary battery 40 and the electrode plate group 41 were disassembled after 300 cycles. As a result, no defects such as precipitation of lithium and separation of active material layer were observed.

Favorable battery characteristics were maintained as described above presumably because a thin film of active material layer was formed in a columnar shape on the surfaces of the projections that are formed without undergoing compression, and thus an effect of reducing the variation in volume caused by expansion of the thin film of active material layer at the time of absorbing lithium and by contraction of the thin film of active material layer at the time of desorbing lithium was exerted.

As described above in the foregoing Examples, since the boundaries between the base and the projections are formed of a curved surface, the electrode plate for a non-aqueous secondary battery of the present invention has excellent processability and excellent releasability of the current collector in the process of compression. In addition, since the end surfaces of the projections of the current collector are formed without undergoing compression, the end surfaces of the projections are free of distortion and have a good surface accuracy, and therefore a uniform thin film of active material layer can be formed. Moreover, since the projections are formed by plastic deformation associated with compression, the surface roughness of the end surfaces of the projections is not reduced and maintains its original surface roughness. Presumably, for this reason, the adhesion with the thin film of active material layer is excellent.

From this point of view, in order to further improve the adhesion between the flat surfaces of the projections and the material mixture layer including electrode active material, it is considered extremely effective to roughen the surface of the current collector before processing beforehand.

The active material layer in the non-aqueous secondary battery of the present invention is preferably formed in a columnar shape on the end surfaces of the projections. By doing this, the variation in volume caused by expansion of the thin film of active material layer at the time of absorbing lithium and by contraction of the thin film of active material layer at the time of desorbing lithium, which occurs as charge/discharge of the non-aqueous secondary battery is repeated, can be reduced. As a result, it is possible to provide a highly reliable, high capacity non-aqueous secondary battery in which defects such as tearing of electrode plate and separation of active material layer are more unlikely to occur.

### INDUSTRIAL APPLICABILITY

The production method of a current collector and an electrode plate for a non-aqueous secondary battery according to the present invention makes it possible to ensure the strength of the current collector for use in producing an electrode plate as well as to allow an electrode active material to be efficiently carried on the projections formed on the current collector, thereby to provide a highly reliable non-aqueous secondary battery which is useful as a power source for portable electronic equipment, the power source being expected to have an improved capacity as electronic equipment and communication equipment become more multi-functional.

1-21. (canceled)

22. A method for producing a current collector for a non-aqueous electrolyte secondary battery using a pair of processing means being disposed such that the surfaces thereof are in press contact with each other to form a press nip for passing a sheet material therethrough and having a plurality of recesses formed on the surface of at least one of the pair of processing means, the method comprising the step of passing a metallic foil for current collector through the press nip between the pair of processing means to perform compression, thereby to form a plurality of projections on at least one surface of the metallic foil for current collector.

23. The production method in accordance with claim 22, wherein the end surfaces of the projections have a surface roughness approximately equal to a surface roughness of the metallic foil for current collector before undergoing the compression.

24. The production method in accordance with claim 22, wherein the cross section of each of the recesses in a direction perpendicular to the surface of the processing means has a tapered shape in which the width of the cross section in a direction parallel to the surface of the processing means gradually narrows from the surface of the processing means toward the bottom of the recess.

25. The production method in accordance with claim 22, wherein the compression is performed such that a volume of the projections is equal to or less than a volume of an internal space of the recesses.

26. The production method in accordance with claim 22, wherein the compression is performed such that the volume of the projections is equal to or less than 85% of the volume of the internal space of the recesses.

27. The production method in accordance with claim 22, wherein in the processing means having the plurality of recesses formed on its surface, each boundary between the recesses and the surface of the processing means is formed of a curved surface.

28. The production method in accordance with claim 27, wherein the curved surface of the boundary between the recesses and the surface of the processing means is formed by forming the recesses by laser machining and removing a bulge produced in the laser machining on the boundary between the recesses and the surface of the processing means.

29. The production method in accordance with claim 28, wherein the bulge is removed by grinding with diamond particles having an average particle size of 30 μm or more and less than 53 μm.

30. The production method in accordance with claim 27, wherein a plurality of grooves each having a width of 1 μm or less and a depth of 1 μm or less are formed on the boundary between the recesses and the surface of the processing means.

31. The production method in accordance with claim 30, wherein the grooves are formed by grinding with diamond particles having an average particle size of 5 μm or less.

32. The production method in accordance with claim 22, wherein the pair of processing means is a pair of rollers having a plurality of recesses formed on a surface of at least one of the pair of rollers.

33. The production method in accordance with claim 32, wherein a surface coating layer containing a cemented carbide or an alloy tool steel or chromium oxide is formed on the surface of the roller having the plurality recesses formed thereon and on the surfaces of the recesses facing the internal space thereof.

34. The production method in accordance with claim 33, wherein a protection layer containing an amorphous carbon material is formed on the surface of the surface coating layer.

35. The production method in accordance with claim 33, wherein the surface coating layer and the protection layer are formed by at least one vapor phase growth method selected from the group consisting of a physical vapor deposition utilizing sputtering, a physical vapor deposition utilizing ion injection, a chemical vapor deposition utilizing heat vapor deposition, and a chemical vapor deposition utilizing plasma vapor deposition.

36. The production method in accordance with claim 22, wherein at least one of a pair of rollers is a roller having a ceramic layer provided on its surface, and a plurality of recesses are formed on the surface of the ceramic layer.

37. The production method in accordance with claim 22, wherein a lubricant is applied and dried on the surface of the roller or on the surface of the metallic foil for current collector.

38. The production method in accordance with claim 37, wherein the lubricant contains a fatty acid.

39. A current collector for a non-aqueous electrolyte secondary battery comprising a base made of a metallic foil for current collector, and a plurality of projections formed so as to extend outwardly from at least one surface of the base, wherein each boundary between the surface of the base and the projections is formed of a curved surface.

40. A method for producing an electrode for a non-aqueous electrolyte secondary battery, the method comprising the step of allowing a positive electrode active material or a negative electrode active material to be carried on the surface of a current collector for a non-aqueous electrolyte secondary battery produced by the method for producing a current collector for a non-aqueous electrolyte secondary battery in accordance with claim 22.

41. A method for producing an electrode for a non-aqueous electrolyte secondary battery, the method comprising the step of allowing a positive electrode active material or a negative electrode active material to be carried on the surface of the current collector for a non-aqueous electrolyte secondary battery in accordance with claim 39.

42. The method for producing an electrode for a non-aqueous electrolyte secondary battery in accordance with claim 40, the method comprising the step of allowing the positive electrode active material or the negative electrode active material to be carried on the surfaces of the projections on the current collector for a non-aqueous electrolyte secondary battery.

43. The method for producing an electrode for a non-aqueous electrolyte secondary battery in accordance with claim 41, the method comprising the step of allowing the positive electrode active material or the negative electrode active material to be carried on the surfaces of the projections on the current collector for a non-aqueous electrolyte secondary battery.

44. A non-aqueous electrolyte secondary battery comprising a positive electrode, a negative electrode, a separator, and a non-aqueous electrolyte, wherein
at least one of the positive electrode and the negative electrode is an electrode produced by the method for producing an electrode for a non-aqueous electrolyte secondary battery in accordance with claim 40.

45. A non-aqueous electrolyte secondary battery comprising a positive electrode, a negative electrode, a separator, and a non-aqueous electrolyte, wherein
at least one of the positive electrode and the negative electrode is an electrode produced by the method for producing an electrode for a non-aqueous electrolyte secondary battery in accordance with claim 41.
